(19) United States
(12) Patent Application Publication
(10) Pub. No.: US 2026/0136515 A1
(43) Pub. Date: May 14, 2026

(54) SRAM 8T STRUCTURE WITH FRONTSIDE AND BACKSIDE INTERCONNECTION OPTIMIZED FOR READ/WRITE PERFORMANCE

(71) Applicant: Taiwan Semiconductor Manufacturing Company, Ltd., Hsin-Chu (TW)

(72) Inventors: Chia-Hao PAO, Kaohsiung City (TW); Kian-Long LIM, Hsinchu City (TW); Ping-Wei WANG, Hsin-chu (TW)

(21) Appl. No.: 19/203,513

(22) Filed: May 9, 2025

Related U.S. Application Data
(60) Provisional application No. 63/718,878, filed on Nov. 11, 2024.

(51) Int. Cl. H10B 10/00; G11C 11/412; G11C 11/419; H10D 89/10

(52) U.S. Cl. CPC H10B 10/12; G11C 11/412; G11C 11/419; H10D 89/10

(57) ABSTRACT

The present disclosure provides a semiconductor structure that includes a substrate having a frontside and a backside; a SRAM circuit having SRAM bit cells formed on the frontside of the substrate, wherein each of the SRAM bit cells includes two inverters cross-coupled together, two write pass gates coupled to the two inverters, a read pull-down device coupled to the two inverters, and a read pass gate coupled to the read pull-down device, and wherein each of the SRAM bit cells is connected to a WBL, a WBLB, a RBL, a Vdd and a Vss; a first subset of WBL, WBLB, RBL, Vdd and Vss is connected to a first SRAM bit cell of the SRAM bit cells from the frontside of the substrate; and a second subset of WBL, WBLB, RBL, Vdd and Vss is connected to the first SRAM bit cell from the backside of the substrate.

### PRIORITY DATA

This application claims priority to U.S. Provisional Patent Application Ser. No. 63/718,878 filed Nov. 11, 2024, the entire disclosure of which is hereby incorporated herein by reference.

### BACKGROUND

An integrated circuit includes various circuits with respective functions, such as a memory circuit having a plurality of memory bit cells to retain information. The memory circuit includes non-volatile devices or volatile devices. For example, the volatile devices include static-random-access memory (SRA M) devices. Three dimensional transistors with fin-type active regions are often desired for enhanced device performance. Those three-dimensional field effect transistors (FETs) formed on fin-type active regions are also referred to as FinFETs. Other three-dimensional field-effect transistors include gate-all-around FETs. Those FETs are required narrow fin width for short channel control, which leads to smaller source/drain regions than those of planar FETs. This will reduce the alignment margins and cause issues for further shrunken device pitches and increasing packing density. Furthermore, when metal interconnect is continuously scaling down to less feature sizes for circuit routing density improvement, the existing interconnect structure schemes face various issues in tighter pitch metal layers. For example, there is metal filling problems due to metal lines or plugs require diffusion barrier metal layer for reliability consideration and the barrier layer further reduce the sizes of the metal lines and metal plugs. These barrier metal layers will impact the trench filling capability and therefore, result in metal resistance degradation or even worse, such as via opening or electro-migration (EM) concern. Other issues with the scaling down of the device sizes include increased routing resistance, increased parasitic capacitance, shorting, leakage, alignment margins, layout flexibility, and packing density. Therefore, there is a need for a structure and method for SRAM structures and method making the same to address these concerns with enhanced circuit performance and reliability, and increased packing density.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion. Various drawings and associated text are provided in a Power Point file. Particularly,

FIG. 1 is a top view of an integrated circuit (IC) structure having static random-access memory (SRAM) devices, constructed according to various aspects of the present disclosure in some embodiments.

FIG. 2 is a schematic view of a SRAM bit cell in the integrated circuit of FIG. 1, in accordance with some embodiments.

FIG. 3A is a top view of a SRAM bit cell in the integrated circuit of FIG. 1, in accordance with some embodiments.

FIG. 3B is a top view of a SRAM bit cell in the integrated circuit of FIG. 1, in accordance with some embodiments.

FIG. 3C is a top view of the IC structure having SRAM bit cells, in portion, in accordance with some embodiments.

FIG. 3D is a top view of the IC structure having SRAM bit cells, in portion, in accordance with some embodiments.

FIG. 3E is a top view of a SRAM bit cell in the integrated circuit of FIG. 1, in accordance with some embodiments.

FIG. 4A is a sectional view of the SRAM bit cell of FIG. 3A along the dashed line AA′, in portion, in accordance with some embodiments.

FIG. 4B is a perspective view of the SRAM bit cell of FIG. 4A, in accordance with some embodiments.

FIG. 5 is a top view of a SRAM bit cell in the integrated circuit of FIG. 1, in accordance with some embodiments.

FIG. 6 is a sectional view of a SRAM bit cell in the integrated circuit of FIG. 1, in accordance with some embodiments.

FIGS. 7A, 7B, 7C, 7D, 7E and 7F are top views of the SRAM bit cell of FIG. 1 in accordance with some embodiments.

FIGS. 8A, 8B, 8C, 8D, 8E and 8F are top views of the SRAM bit cell of FIG. 1 in accordance with some embodiments.

FIGS. 9A, 9B, 9C and 9D are top views of the SRAM bit cell of FIG. 1 in accordance with some embodiments.

FIGS. 10A, 10B, 10C and 10D are top views of the SRAM bit cell of FIG. 1 in accordance with some embodiments.

FIG. 11 is a flowchart of a method of generating an asymmetric layout of an integrated circuit having a plurality of SRAM cells, constructed in accordance with some embodiments.

FIG. 12 is a flowchart of a method of generating an asymmetric layout of an integrated circuit structure having a plurality of SRAM cells, constructed in accordance with some embodiments.

FIGS. 13A-23A, FIGS. 13B-23B, FIGS. 13C-23C, and FIGS. 13D-23D are fragmentary diagrammatic views of an integrated circuit structure, in portion or entirety, at various fabrication stages (such as those associated with the method in FIG. 12) according to various aspects of the present disclosure.

FIGS. 24-27 are fragmentary diagrammatic views of an integrated circuit structure, in portion or entirety, at various fabrication stages (such as those associated with the method in FIG. 12) according to various aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Still further, when a number or a range of numbers is described with “about,” “approximate,” and the like, the term is intended to encompass numbers that are within +/−10% of the number described, unless otherwise specified. For example, the term “about 5 nm” encompasses the dimension range from 4.5 nm to 5.5 nm.

The present disclosure provides various embodiments of a 8-transistor (8T) static-random-access memory (SRAM) device structure and a method making the same. Particularly, the present disclosure provides various embodiments of the SRAM device structure with power lines (such as higher power lines Vdd, lower power lines and Vss), bit lines and word lines distributed on the frontside and backside of the substrate such that the overall device performance is enhance among various trade-off parameters, such as metal routing resistance and parasitic capacitance.

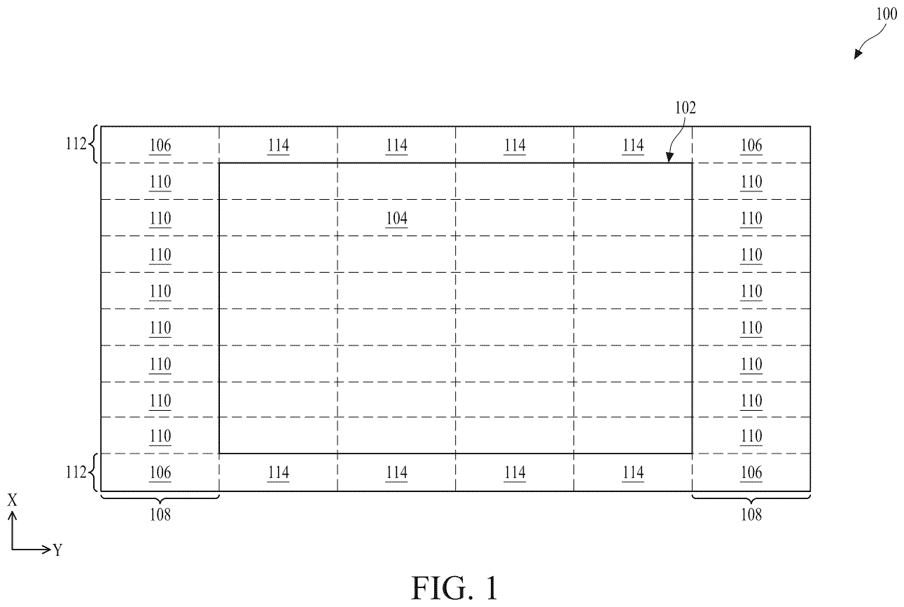

FIG. 1 is a top view of an integrated circuit (IC) structure 100 constructed according to various aspects of the present disclosure in one embodiment. In some embodiments, the IC structure 100 is formed on active regions and includes various field-effect transistors (FETs). In some embodiments, the IC structure 100 is formed on fin active regions and includes fin field-effect transistors (FinFETs). In some embodiments, the IC structure 100 includes other three-dimensional active regions, such as multiple channels vertically stacked on the substrate. The corresponding FET has a gate stack wrapping around each of the multiple channels that are vertically stacked, therefore also being referred to as gate-all-around FET structure, or nanotube or nanosheet FET structure. The integrated circuit structure 100 includes a static-random-access memory (SRAM) circuit having a SRAM array 102, which further includes a plurality of SRAM bit cells (or SRAM cells) 104 configured in an array, spanning into multiple columns and multiple rows. The IC structure 100 may further include other devices/circuit modules (such as logic devices, high-frequency devices, image-sensing devices, dynamic-random-access memory (DRAM) devices or a combination thereof) integrated with the SRAM devices. In the present embodiments, each column of the SRAM bit cells 104 in the array spans along the X direction and each row spans along the Y direction. For examples, each column may include N₁ SRAM bit cells configured in a line (a column) along the X direction, and each row may include N₂ SRAM bit cells configured in a line (a row) along the Y direction. In other words, the SRAM array 102 includes SRAM bit cells configured in N₁ rows and N₂ column. In some examples of the SRAM array 102, each column includes 8, 16, 32, 64 or 128 SRAM bit cells, and each row may include 4, 8, 16, or 32 SRAM bit cells. In the example illustrated in FIG. 1, the SRAM array 102 includes 4 columns and 8 rows.

In some embodiments, the IC structure 100 further includes corner dummy cells 106 disposed on four corners of the SRAM array 102 and edge straps, such as word-line edge straps (WL edge straps) 108 disposed on raw edges of the SRAM array 102 and bit-line edge straps (BL edge straps) 112 disposed on column edges of the SRAM array 102. Each WL edge strap 108 includes a plurality of WL edge cells 110 configured in a line along X direction and each BL edge strap 112 includes a plurality of BL edge cells 114 configured in a line along Y direction. Those edge straps (108 and 110) are circuit regions not designed to serve as SRAM bit cells but to provide other functions as described later.

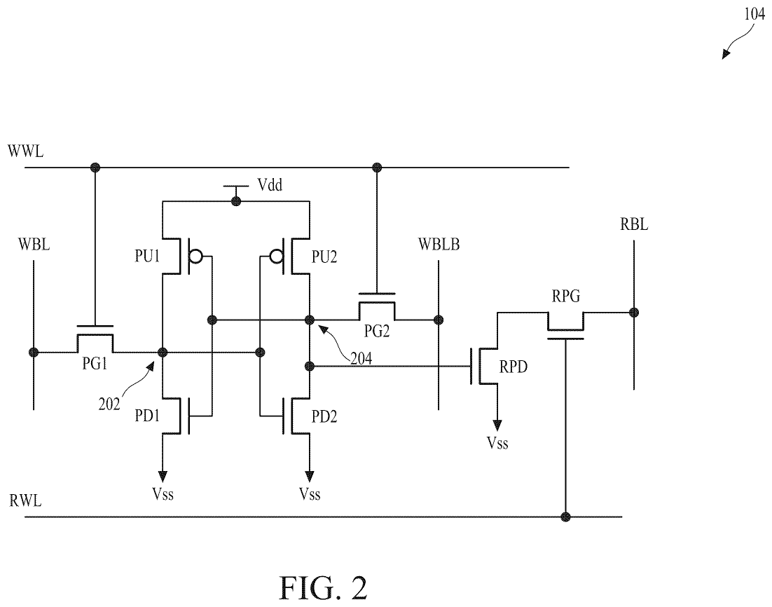

FIG. 2 is a schematic view of the SRAM bit cell (or simply SRAM cell) 104 constructed in accordance with some embodiments. Particularly, the SRAM bit cell 104 includes eight transistors (8T) configured and connected to form storage nodes accessed and controlled by dual ports: a read port and a write port, therefore also be referred to as an 8T SRAM bit cell. Each SRAM bit cell 104 includes two inverters cross-coupled together to store a bit of data and further includes a read port and a write port electrically connected to the two inverters for reading from and write into the SRAM bit cell. For example, write word line (WWL) and read word line (RWL) control access to the storage nodes; and word bit line (WBL), word bit line bar (WBLB), and read bit line (RBL) serve for read/write operations.

Particularly, the SRAM bit cell 104 includes a first pull-up device (“PU1”) and a first pull-down device (“PD1”) connected into a first inverter. The SRAM bit cell 104 further includes a second pull-up device (“PU2”) and a second pull-down device (“PD2”) connected into a second inverter. The first and second inverters are cross-coupled and form a data storage unit. The SRAM bit cell 104 includes a write port having two pass gate devices (“PG1” and “PG2”) electrically connected to the two inverters for data writing. The SRAM bit cell 104 further includes a read port having a read pull-down device (“RPD) and a read pass gate device (“RPG”) electrically connected to the two inverters for data reading, as illustrated in FIG. 2. In some embodiments, the pull-up devices PU1 and PU2 are p-type FETs (pFETs) formed in a n-type doped well (n-well), such as pFETs having a fin structure or a GAA structure; and the pull-down devices PD1, PD2 and RPD, and pass gate devices PG1, PG2 and RPG are n-type FETs (nFETs) formed in a p-type doped well (p-well), such as nFETs having a fin structure or a GAA structure.

In some embodiments, the pull-down devices, the pull-up devices and the pass gate devices each may include more than one corresponding FET or different number of FETS to tune the SRAM bit cell performance, such as sink current, access speed, and/or device reliability. For example, the number of FETs in the pull-down devices is greater than the number of FETs in the pass-gate devices. In some embodiments, those additional pull-down devices may be formed in additional fin active regions. Alternatively, the SRAM bit cell 104 is formed on vertically-stacked channels but the pull-down devices of the SRAM bit cell 104 are formed on vertically-stacked channels with a greater number of channels than those for pass-gate devices or pull-up devices.

Specifically, the drains of the first pull-up device (PU1) and the first pull-down device (PD1) are electrically connected together, defining a first drain node (or first node) 202. The drains of the second pull-up device (PU2) and the second pull-down device (PD2) are electrically connected together, defining a second drain node (or second node) 204. The gate electrodes of PU1 and PD1 are electrically connected together and coupled to the second node 204. The gate electrodes of PU2 and PD2 are electrically connected together and coupled to the first node 202. The sources of PU1 and PU2 are electrically connected to the power line (Vdd line). The sources of PD1 and PD2 are electrically connected to a complementary power line (Vss line), such as ground line. Note that a gate electrode and a pass gate device are different: a gate electrode is a component of a FET while a pass gate device is a FET functioning as a pass gate of the SRAM cell.

Still referring to FIG. 2, the SRAM bit cell 104 includes dual ports: a write port for data writing and a read port for data reading. The write port includes the first pass gate device (PG1) and the second pass gate device (PG2). The pass-gate devices each includes a n-type FET. In some embodiments, each pass gate may include more than one FET as noted above. The drain of PG1 is electrically connected to a write bit line (“WBL”); the source of PG1 is electrically connected to the first node 202; and the gate electrode of PG1 is electrically connected to a write word line (“WWL”). Similarly, the drain of PG2 is electrically connected to a complimentary write bit-line or write bit-line bar (“WBLB”); the source of PG2 is electrically connected to the second node 204; and the gate electrode of PG2 is electrically connected to the write word line (“WWL”).

The read port includes the read pull-down device (RPD) and the read pass gate device (RPG). RPD and RPG each includes a n-type FET. In some embodiments, each of RPD and RPG may include more than one FET as noted above.

The gate electrode of RPD is electrically connected to the second node 204 or the common drain of PD2 and PU2; the source of RPD is electrically connected to the power line Vss; and the drain of RPD is electrically connected to the source of RPG. As to RPG, the source of RPG is electrically connected to the drain of RPD; the drain of RPG is electrically connected to read bit line (RBL); and the gate electrode of RPG is electrically connected to the read word line (RWL).

Various nFETs and pFETs may be formed by any proper technology, such as fin-like FETs (FinFETs) that includes n-type FinFETs (nFinFETs) and p-type FinFETs (pFinFETs). In one embodiment, the various nFinFETs and pFinFETs are formed by a process including etching a semiconductor to form trenches, partially filling (such as by a procedure that includes deposition, chemical mechanical polishing and etching to recess) the trenches to form shallow trench isolation (STI) features and fin active regions. In furtherance of the present embodiment, an epitaxy semiconductor layer is selectively formed on the fin active region. In another embodiment, the various FinFETs are formed by a process including depositing a dielectric material layer on the semiconductor substrate, etching the dielectric material layer to form openings thereof, selective epitaxy growing a semiconductor material (such as silicon) on the semiconductor substrate within the openings to form fin active regions and STI features. In another embodiment, the various FinFETs may include strained features for enhanced mobility and device performance. For example, the pFinFETs may include epitaxy grown silicon germanium on a silicon substrate. The nFinFETs may include epitaxy grown silicon carbide on the silicon substrate. In another embodiment, the gate stacks in various FinFETs are formed using high k/metal gate technology, in which the gate dielectric layer includes a high-k dielectric material, and the gate electrode includes metal.

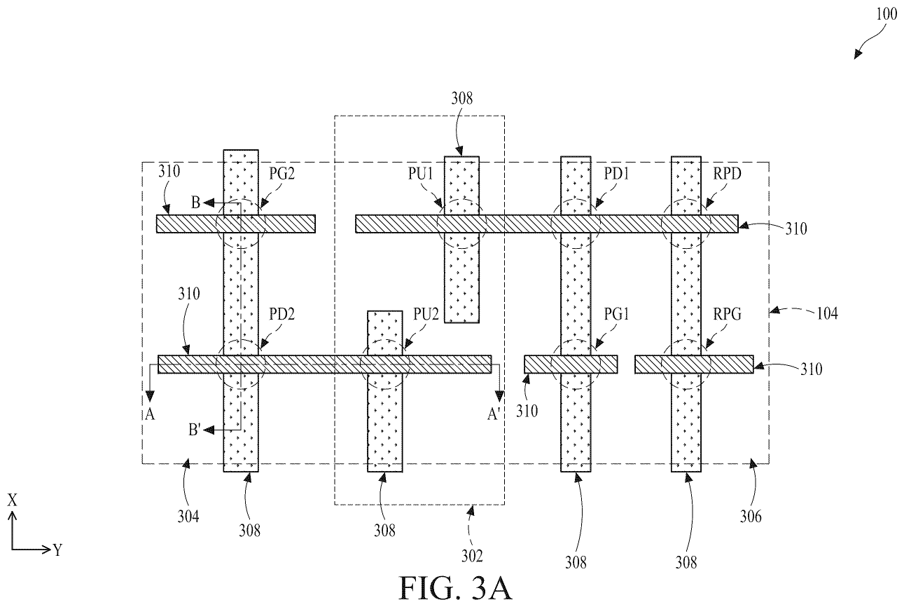

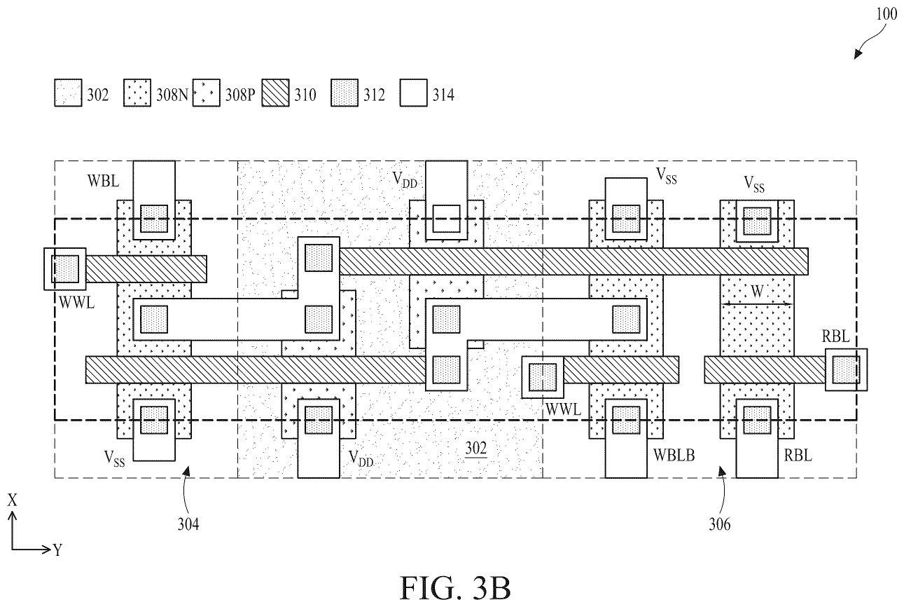

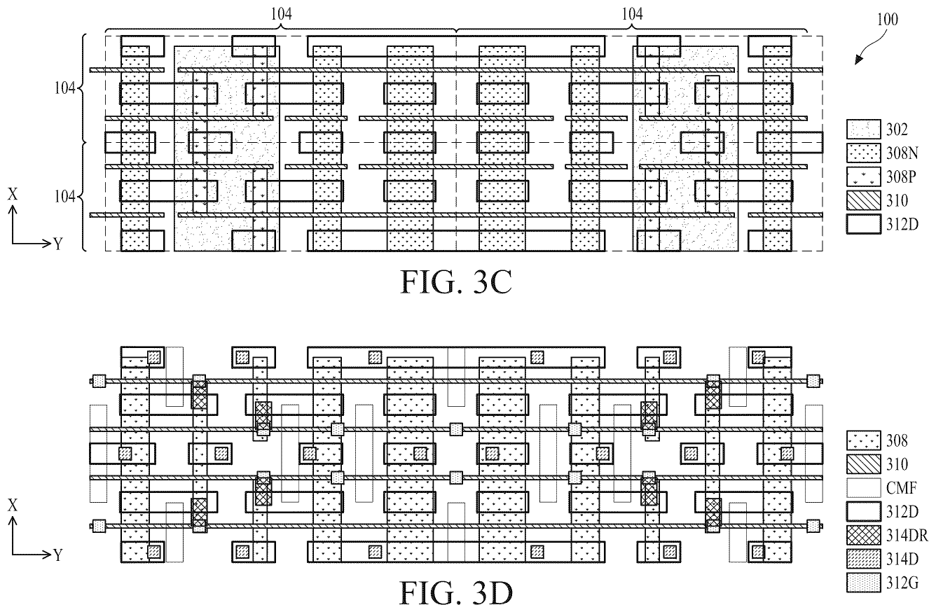

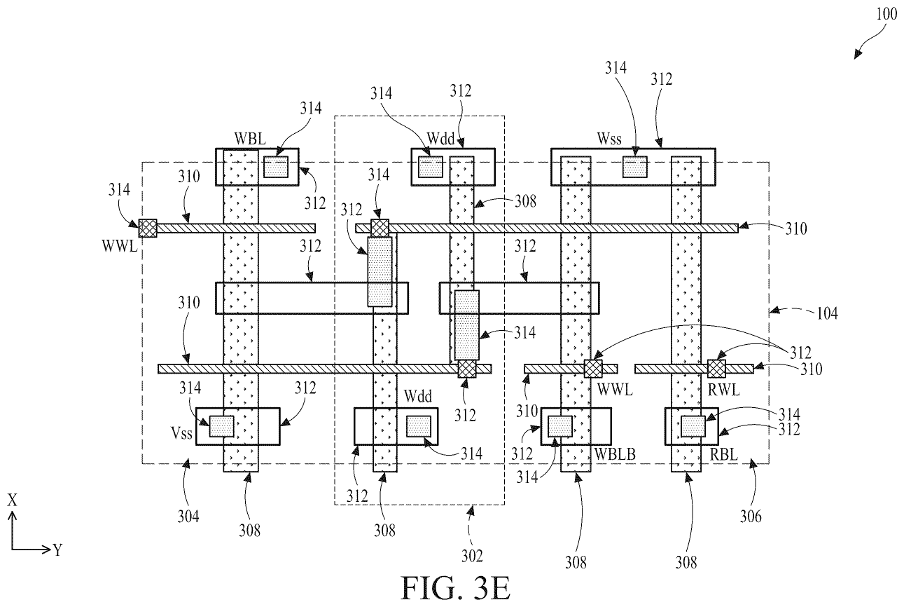

FIGS. 3A and 3B are top views of the IC structure 100, in portion, particularly a SRAM bit cell 104, constructed in accordance with some embodiments. The IC structure 100 is formed on a substrate having a top surface defined by a X direction and a Y direction orthogonal to each other. A normal direction of the top surface of the substrate is a Z direction orthogonal to the X and Y directions. The X, Y and Z directions constitute Cartesian coordinates. The IC structure 100 includes a SRAM bit cell 104 having eight transistors configured and connected with a schematic structure illustrated in FIG. 2.

As illustrated in FIG. 3A, the integrated circuit structure 100 includes a n-type doped well (n-well) 302 formed in the center of the SRAM bit cell 104. The n-well 302 may have an elongated shape longitudinally oriented in the X direction and may extend along the X direction over multiple SRAM bit cells. The integrated circuit structure 100 includes a first p-type doped well (p-well) 304 and a second p-well 306 disposed on sides of the n-well 302, each with elongated shape longitudinally oriented in the X direction. In some embodiments, the p-wells 304 and 306 may extends along the X direction over multiple SRAM bit cells as well. The integrated circuit structure 100 includes various active regions 308 disposed in the respective doped wells (such as 302, 304 and 306) with various FETs formed thereon. Those active regions 308 are surrounded and defined by isolation features, such as STI features. In some embodiments, the active regions 308 have elongated shapes longitudinally oriented along the X direction and may extend over multiple SRAM bit cells 104. In some embodiments, the active regions 308 are fin-like active regions (or simply fin active regions) protruded above the isolation features (such as STI features). The IC structure 100 also includes gate structures 310 formed on the active regions 308 and longitudinally oriented along the Y direction. In the disclosed embodiment, the SRAM bit cell 104 includes one active region 308 in the p-well 304, two active regions 308 in the n-well 302, and two active regions 308 in the p-well 306.

Especially, some gate structures 310 extend from the n-well 302 to the adjacent p-well (such as 304 or 306) such that corresponding FETs (such as PU1 and PD1, or PU2 and PD2) share a common gate. In the present embodiment, the gate structure 310 over both n-well 302 and p-well 304 is associated with a pFET for the second pull-up device (PU2) in the n-well 302 and an nFET for the second pull-down device (PD2) in the p-well 304; the gate structure 310 over both n-well 302 and p-well 306 is associated with a pFET for the first pull-up device (PU1) in the n-well 302 and a nFET for the first pull-down device (PD1) in the p-well 306. The nFET for the first pass gate device (PG1) is formed in the p-well 306; and the nFET for the second pass gate device (PG2) is formed in the p-well 302. PD2 and PG2 are formed on the same active region 308 in the p-well 304; and PD1 and PG1 are formed on the same active region 308 in the p-well 306.

Especially, the SRAM bit cell 104 of the IC structure 100 is an 8T SRAM bit cell and further includes a read pull-down device (RPD) and a read pass gate device (RPG) formed on a second active region 308 within the p-well 306. The second active region 308 is disposed next to and configured in parallel with the first active region 308 (associated with PD1 and PG2) in the p-well 306; and is longitudinally oriented along the X direction. The common gate structure 310 of PD1 and PU1 is further extend along the Y direction and functions as the gate structure of RPD.

FIG. 3B is similar to FIG. 3A and further includes additional features, such as various overlying conductive features configured to connect FETs into the 8T SRAM cell 104 of FIG. 2. Note that various figure reference numbers, such as FETs, are not labeled in FIG. 3B for simplicity and better view. The IC structure 100 further includes various contacts 312, and conductive features 314 overlying and landing on the corresponding contacts 312. In some embodiment, the conductive features 314 are metal lines of a first metal layer in the interconnect structure. In some embodiment, the conductive features 314 are vias or elongated vias underlying the first metal layer in the interconnect structure. In the following descriptions, the conductive features 314 are also referred to as vias 314, even though those may be vias in some embodiments, or may be metal lines in other embodiment. As described later in detail, those contacts 312 and the conductive features 314 are distributed on the frontside interconnect structure and the backside interconnect structure. Particularly, active regions 308 are separately labeled as 308N and 308P, in which 308N represents n-type doped active regions disposed in the p-well 304 or p-well 306 while 308P represents p-type doped active regions disposed in the n-well 302. The contacts 312 and the conductive features 314 are configured to connect common source/drain features or connect a source/drain feature to a gate electrode.

Specifically, those contacts 312 are connected to write word line (WWL), write bit line (WBL), write bit line bar (WBLB), read bit line (RBL), read word line (RWL), power line (Vdd), and ground line (Vss or GND), respectively; and the vias 314 are connected to the corresponding contacts 312. When a contact 312 is formed on one side (such as the frontside or the backside), the corresponding via 314 is formed on the same side as well and is landing on that contact 312; and the contacts 312 and vias 314 formed on the backside are referred to as backside contacts 312B and backside vias 314B for clarification. Especially, a first subset of the contacts 312 and conductive features 314 are distributed on the frontside of the substrate and a second subset of the contacts 312 and conductive features 314 are distributed on the backside of the substrate, which will be further described later in detail.

FIG. 3C is a top view of the IC structure 100, in portion, constructed according to some embodiments, and FIG. 3D is a top view of the IC structure 100, in portion, constructed according to some embodiments. FIG. 3C is similar to FIG. 3A but includes a plurality of SRAM bit cells 104 configured in an array. FIG. 3D is similar to FIG. 3C but includes more features, such as gate contacts, vias to S/D contacts and vias to gate contacts. Particularly, FIG. 3D includes gate cut features to cut long gate structures into segmented gate structures as illustrated in FIG. 3C. FIGS. 3C and 3D are collectively described. In the illustrated embodiment in FIGS. 3C and 3D, four SRAM bit cells 104 are configured as an array along the X and Y directions. Each SRAM cell 104 includes active regions 308 and gate structures 310. Some active regions 308 and some gate structures 310 may extend through more than one SRAM cell 104. Further, each SRAM cell 104 further includes various conductive features configured to connect FETs into the 8T SRAM cell 104 of FIG. 2. In the disclosed embodiment, the IC structure 100 further includes contacts 312D landing on source/drain features (simply S/D contacts 312D), and vias 314D landing on S/D contacts 312D, and may further include elongated vias 314DR landing on some S/D contacts 312D. The elongated vias 314DR may function as butted contact to connect a gate structure to a S/D feature. The IC structure 100 also includes contacts 312G (simply gate contacts 312G) landing on gate structures 310. A S/D contact 312D is landing on a respective S/D feature, and a S/D via 314D is landing on the respective S/D contact 312D, thereby connecting the corresponding S/D feature to a proper signal (such as a bit line) or power line (such as Vss or Vdd). Similarly, a gate contact 312G is landing on a gate structure 310, thereby connecting the corresponding gate structure to a proper feature or signal line (such as a word line). As described later, those conductive features are designed to distribute on both the frontside and the backside of the substrate so to address various issues mentioned early. More particularly, the IC structure 100 includes a frontside interconnect structure formed on the frontside of the substrate and a backside interconnect structure formed on the backside of the substrate. Various contacts and vias are properly distributed on the frontside and the backside of the substrate according to various embodiments.

FIG. 3E is a top view of the IC structure 100, in portion, constructed according to some embodiments. FIG. 3E is similar to FIG. 3D and further only includes one SRAM cell 104 for better view. The SRAM cell 104 includes a n-well 302; p-wells 304 and 306; active regions 308 formed on the doped wells; and gate structures 310 formed on the active regions 308. The SRAM cell 104 further includes various conductive features configured to connect FETs into the 8T dual port SRAM cell 104. Note that various figure reference numbers, such as FETs, are not labeled in FIG. 3E for simplicity and better view. The sources of the PU1 and PU2 are connected to a first power line Vdd with a higher voltage; the sources of the PD1 and PD2 are connected to a second power line Vss with a lower voltage (e.g., a grounding line); the drain of the PG1 is connected to a write bit-line (WBL); the gate of the PG1 is connected to a write word-line (WWL); the drain of the RPG is connected to a read bit-line (RBL); and the gate of the RPG is connected to a read word-line (RWL). In the present embodiment of the integrated circuit structure 100, each SRAM cell includes a first Vss and a second Vss.

The SRAM cell 104 includes various contacts 312, and conductive features 314 overlying and landing on the corresponding contacts 312. In some embodiment, the conductive features 314 are metal lines of a first metal layer in the interconnect structure. In some embodiment, the conductive features 314 are vias or elongated vias underlying the first metal layer in the interconnect structure. In the following descriptions, the conductive features 314 are also referred to as vias 314, even though those may be vias in some embodiments, or may be metal lines in other embodiment. The contacts 312 include contacts 312D landing on source/drain features (or simply referred to as S/D contacts 312D), contacts 312G landing on gate structures (or simply referred to as gate contacts 312G), vias 314D landing on S/D contacts 312D (or simply referred to as S/D vias 314D), and elongated vias 314DR landing on S/D contacts 312D (or simply referred to as S/D slot vias 314DR). As described later in detail, those contacts 312 and the conductive features 314 are distributed on the frontside interconnect structure and the backside interconnect structure. Particularly, active regions 308 are separately labeled as 308N and 308P, in which 308N represents n-type doped active regions disposed in the p-well 304 or p-well 306 while 308P represents p-type doped active regions disposed in the n-well 302. The contacts 312 and the conductive features 314 are configured to connect common source/drain features or connect a source/drain feature to a gate electrode.

Specifically, those contacts 312 are connected to write word line (WWL), write bit line (WBL), write bit line bar (WBLB), read bit line (RBL), read word line (RWL), power line (Vdd), and ground line (Vss or GND), respectively; and the vias 314 are connected to the corresponding contacts 312. When a contact 312 is formed on one side (such as the frontside or the backside), the corresponding via 314 is formed on the same side as well and is landing on that contact 312; and the contacts 312 and vias 314 formed on the backside are referred to as backside contacts 312B and backside vias 314B for clarification. Especially, a first subset of the contacts 312 and conductive features 314 are distributed on the frontside of the substrate and a second subset of the contacts 312 and conductive features 314 are distributed on the backside of the substrate, which will be further described later in detail.

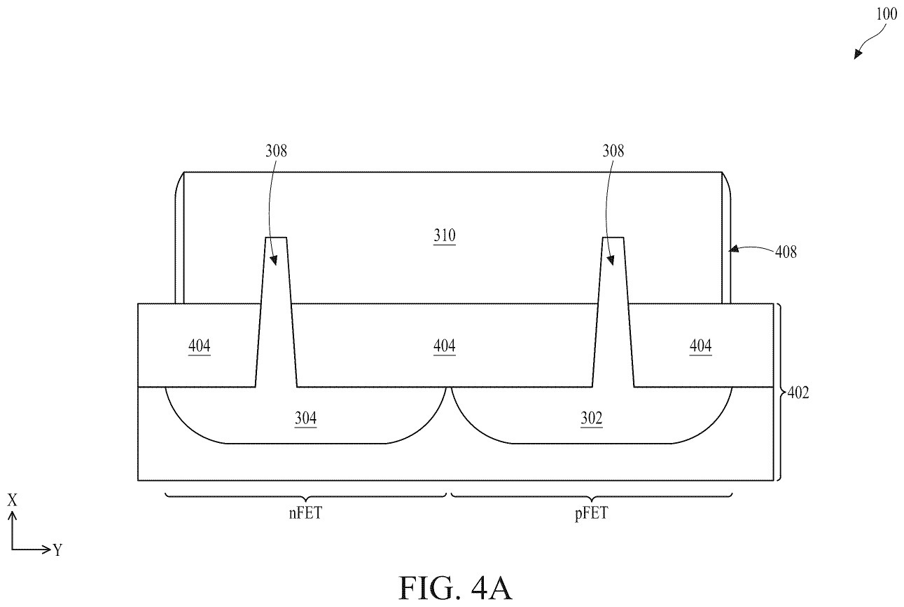

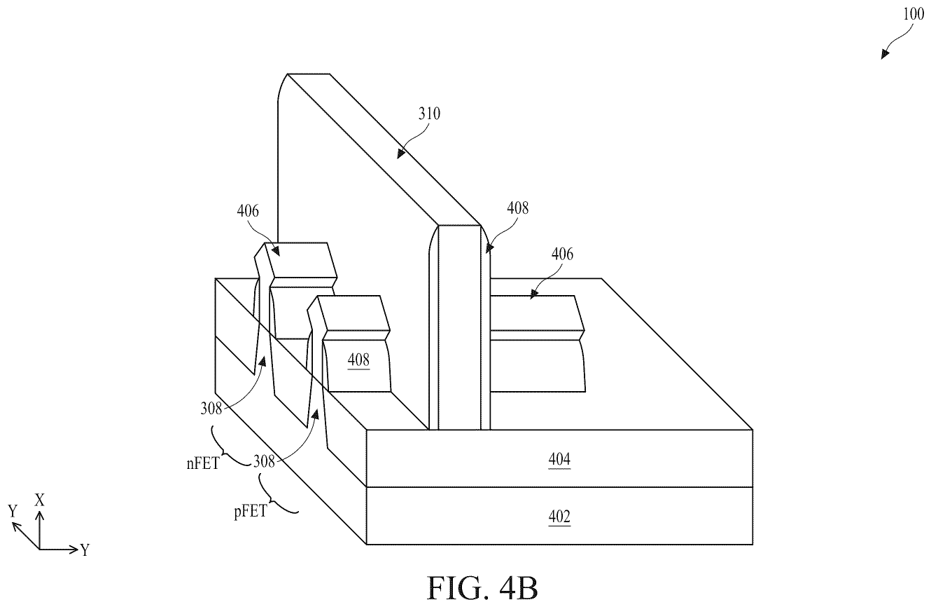

FIG. 4A is a sectional view of the IC structure 100, in portion, such as cut along the dashed line AA′ of FIG. 3A, constructed in accordance with some embodiments. FIG. 4B is a perspective view of the integrated circuit structure 100 of FIG. 4A, in portion, constructed in accordance with some embodiments. In FIGS. 4A and 4B, the IC structure 100 includes a semiconductor substrate 402. The semiconductor substrate 402 includes silicon. Alternatively, the semiconductor substrate 402 includes germanium, silicon germanium or other proper semiconductor materials. The integrated circuit structure 100 includes various isolation features 404, such as shallow trench isolation (STI) features. The IC structure 100 also includes various active regions 308, such as fin active regions, formed on the semiconductor substrate 402. In the illustrated embodiment where the active regions 308 are fin-like, the active regions 308 are extruded above the isolation features 404 and are surrounded and isolated from each other by the isolation features 404. The IC structure 100 also includes a p-well 304 and a n-well 302 formed on the semiconductor substrate 402. Various FETs are formed on the active regions 308. A nFET is disposed on the active regions 308 within the p-well 304 and a pFET is disposed on the active regions 308 within the n-well 302.

Source/drain (S/D) features 406 are formed on the active regions 308, and a gate structure 310 is formed on the active region 308 and disposed between the corresponding S/D features 406. In the present example, the gate structure 310 extends over from the first active region 308 within the p-well 304 to the second active region 308 within the n-well 302, therefore as a common gate shared by the corresponding nFET and pFET. The gate structure 310 includes a gate dielectric layer and a gate electrode disposed on the gate dielectric layer. Dielectric spacers 408 may be further formed on sidewalls of the gate structure 310 and sidewalls of the active regions 308 as well. a gate dielectric layer and a gate electrode are also collectively referred to as a gate stack. A gate structure 310 includes a gate stack and gate spacers 408 disposed on sidewalls of the gate stack. The gate stack further includes a gate dielectric layer and a gate electrode disposed on the gate dielectric layer. In some embodiments, the gate dielectric layer includes an interfacial layer (such as silicon oxide) and a high-k dielectric layer (such as hafnium oxide, hafnium nitride, other suitable metal oxide, other suitable metal nitride or combinations thereof) disposed on the interfacial layer. In some embodiments, the gate electrode includes a work function metal layer, a capping metal layer, a glue metal layer, a fill metal layer or a combination thereof. A channel is a portion of the active region 308 underlying the corresponding gate stack. The corresponding S/D features 406; the gate structure 310; and the channel are configured and connected into a field effect transistor, such as a nFET or a pFET.

In various embodiments, the isolation features 404 utilize a proper isolation technology, such as local oxidation of silicon (LOCOS) and/or shallow trench isolation (STI), to define and electrically isolate the various regions. The isolation feature 404 includes silicon oxide, silicon nitride, silicon oxynitride, other suitable dielectric materials, or combinations thereof. The isolation feature 404 is formed by any suitable process. As one example, forming STI features includes using a lithography process to expose a portion of the substrate, etching a trench in the exposed portion of the substrate (for example, by using a dry etching and/or wet etching), filling the trench (for example, by using a chemical vapor deposition process) with one or more dielectric materials, and planarizing the substrate and removing excessive portions of the dielectric material(s) by a polishing process, such as CMP. In some examples, the filled trench may have a multi-layer structure, such as a thermal oxide liner layer filled with silicon nitride or silicon oxide.

In another embodiment, the gate structures 310 alternatively or additionally include other proper materials for circuit performance and manufacturing integration. For example, the gate dielectric layer includes high k dielectric material layer, such as metal oxide, metal nitride or metal oxynitride. In various examples, the high k dielectric material layer includes metal oxide (such as ZrO2, Al2O3, and HfO2) or metal nitride or other suitable dielectric material, formed by a suitable deposition method. The gate dielectric layer may further include an interfacial layer interposed between the semiconductor substrate 402 and the high k dielectric material. In some embodiments, the interfacial layer includes silicon oxide.

The gate electrode includes metal, such as aluminum, copper, tungsten, metal silicide, doped polysilicon, other proper conductive material or a combination thereof. The gate electrode may include multiple conductive films designed such as a capping layer, a work function metal layer, a blocking layer and a filling metal layer (such as aluminum or tungsten). multiple conductive films designed for work function matching to a nFET and a pFET, respectively. In some embodiments, the gate electrode for nFET includes a work function metal with a composition designed with a work function equal 4.2 eV or less and the gate electrode for pFET includes a work function metal with a composition designed with a work function equal 5.2 eV or greater. For examples, the work function metal layer for nFET includes tantalum, titanium aluminum, titanium aluminum nitride or a combination thereof. In other example, the work function metal layer for pFET includes titanium nitride, tantalum nitride or a combination thereof.

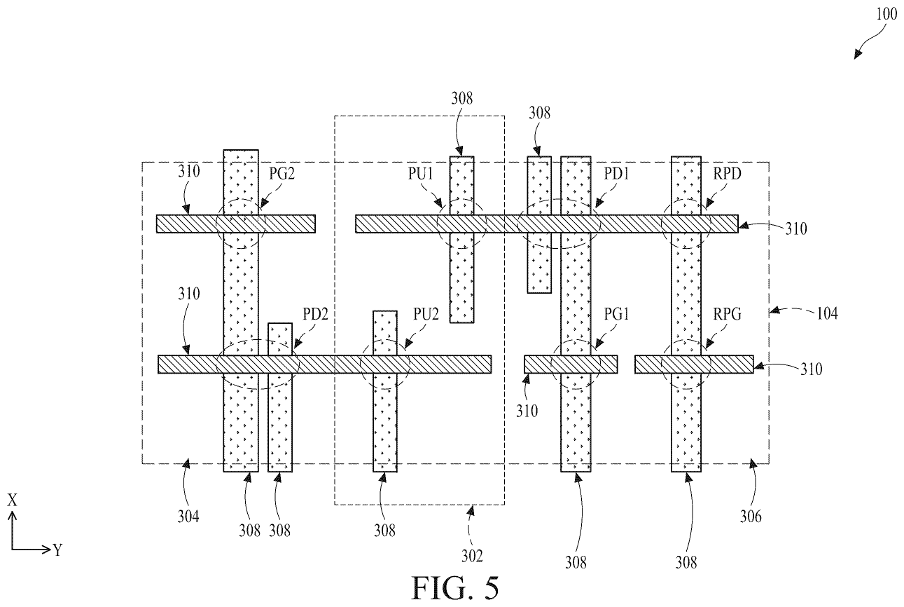

FIG. 5 is a top view of the IC structure 100 in portion, particularly a SRAM bit cell 104, constructed in accordance with some embodiments. As illustrated in FIG. 5, the IC structure 100 includes two or more first pull-down (PD-1) devices formed on a number (N) of fin active regions 308 within the p-well 304 and two or more second pull-down (PD-2) devices formed on the number (N) of fin active regions 308 within the p-well 306. In the depicted example, the number N is 2. In other examples, the number N may be 3, 4 or etc.

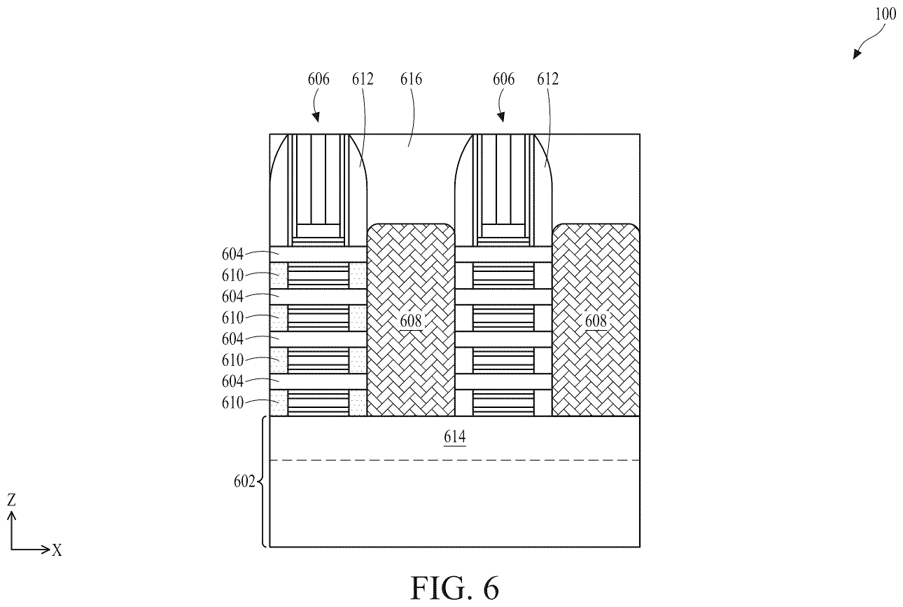

FIG. 6 is a sectional view of the IC structure 100, in portion, such as cut along the dashed line BB′ of FIG. 3A, constructed in accordance with some embodiments. In FIG. 6, the IC structure 100 has a vertically-stacked channel structure, in which multiple channels are vertically stacked. Especially, the IC structure 100 includes a substrate 602 and multiple channels 604 formed over the substrate 602. The IC structure 100 further includes a gate structure 606 formed around the channels 604 and source/drain (S/D) features 608 disposed on both sides of the gate structure 606. Particularly, the gate structure 606 wraps around each of the vertically-stacked multiple channels 604 that span between the S/D features 608 disposed on the both sides of the gate structure 606. The IC structure 100 further includes other features, such as inner spacers 610 (of one or more dielectric material) interposed between the gate structure 606 and the S/D features 608; gate spacers 612 disposed on sidewalls of the gate structure 606; a doped wall 614 (such as an N-well or a P-well); and an interlevel dielectric (ILD) layer 616. The gate structure 606 includes a gate dielectric layer and a gate electrode. The gate dielectric layer includes one or more dielectric material, such as a high-k dielectric material. The gate dielectric layer may further include an interfacial layer (such as silicon oxide) underlying the high-k dielectric material. The gate electrode includes one or more conductive material, such as a capping layer, a work functional metal and a fill metal. Accordingly, the various nFETs and pFETs of the SRAM bit cell 104 are formed those vertically-stacked channels. Furthermore, the first number N1 of the channels for a pull-down device and the second number N2 of the channels for a pull-up device may be designed differently to tune the performance of a SRAM cell. For example, the ratio N1/N2 is designed to be greater than 1, such as N1/N2=2/1; 3/2; 5/3; and so on.

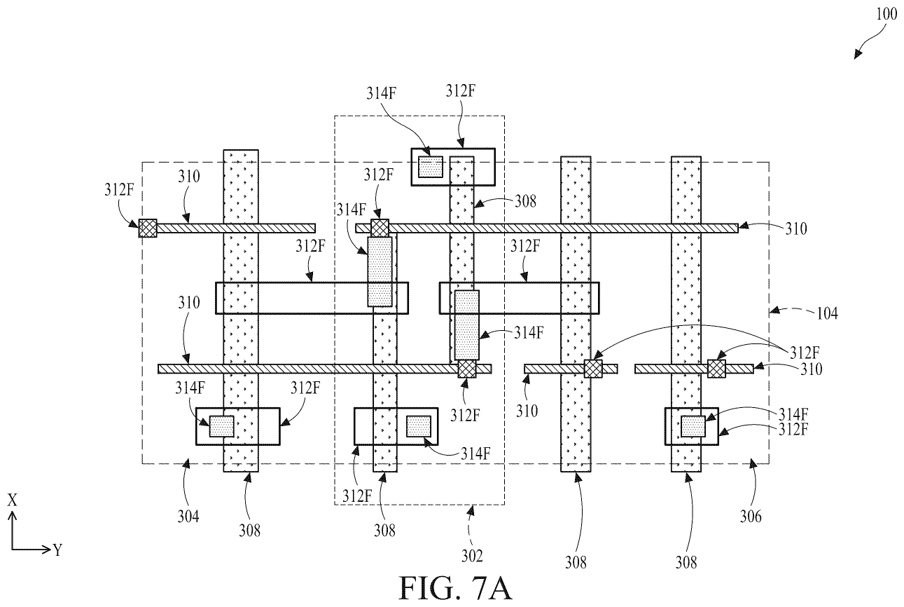

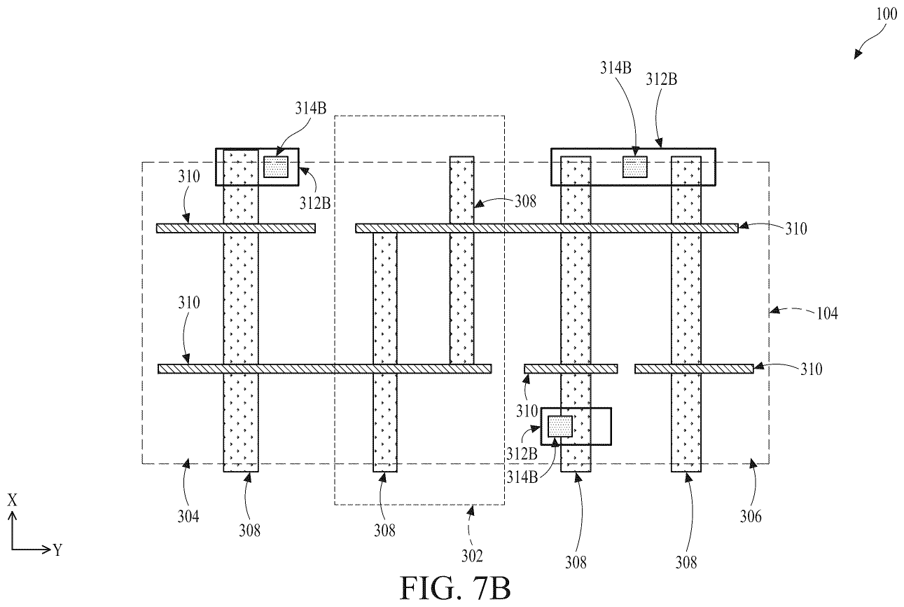

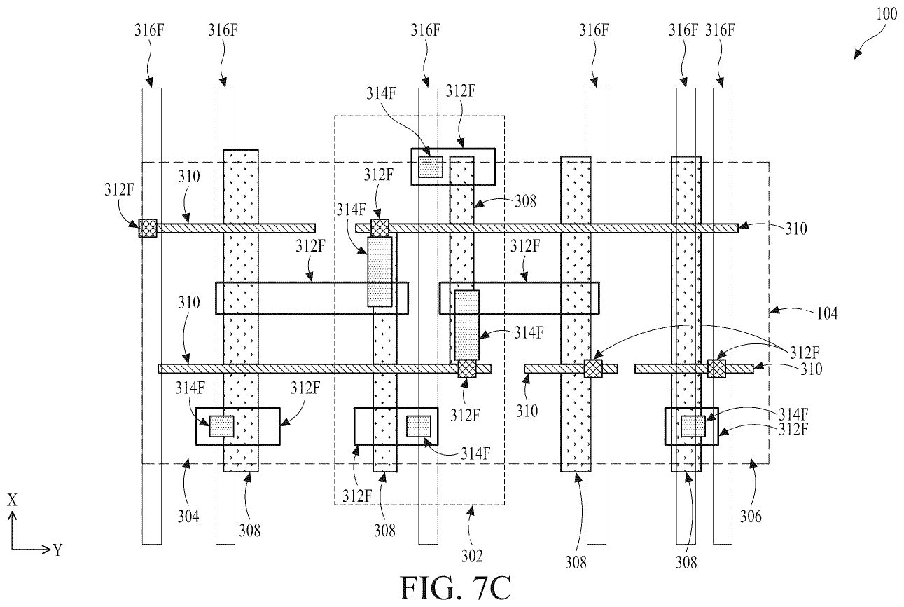

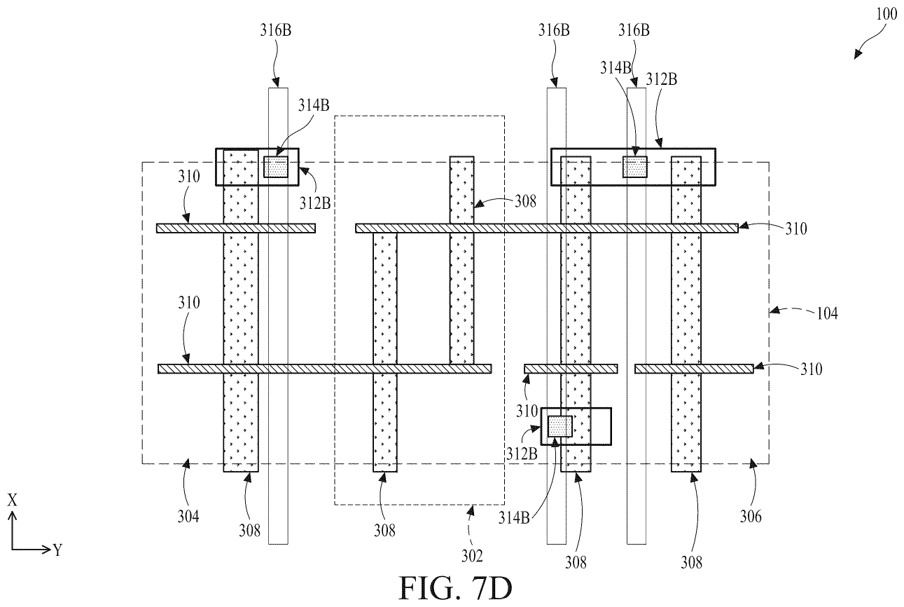

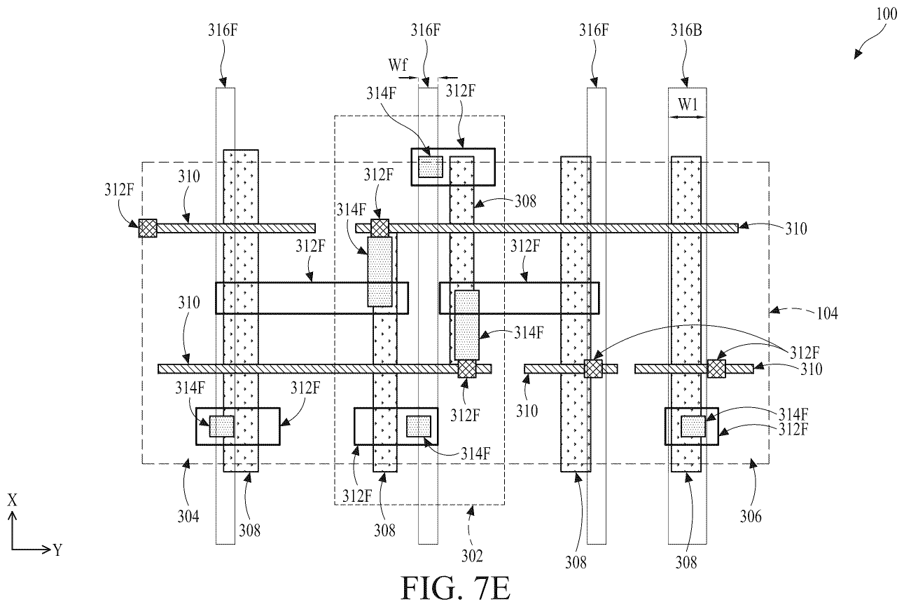

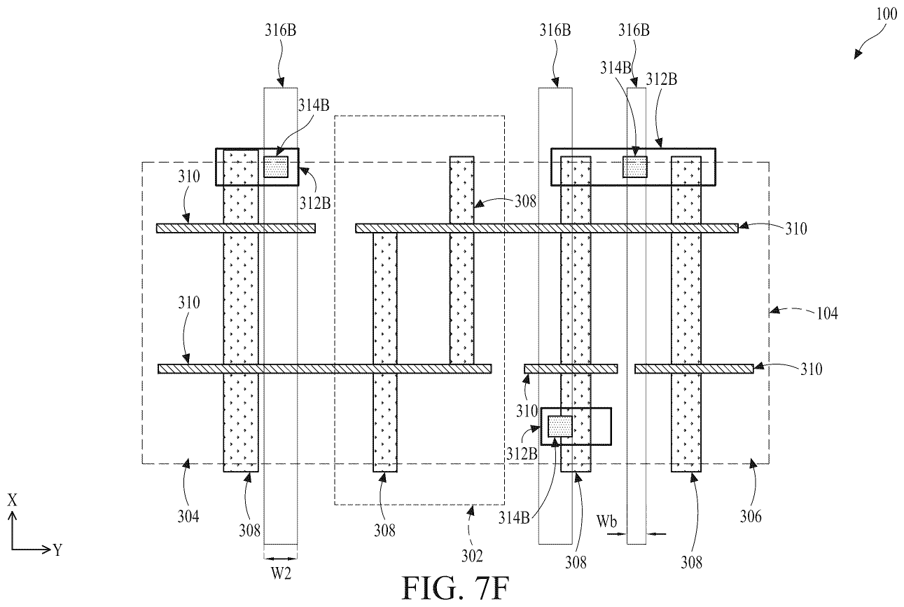

Those FETs of the SRAM bit cell 104 are further connected to form a functional SRAM circuit, such as illustrated in. FIG. 7. Those conductive features are designed to connects various features (such as gate structures and S/D features) of the FETs in the SRAM cells) to form various SRAM cells 104 according to FIG. 2. An interconnect structure includes various conductive features, such as contacts (contact features); vias (via features) and metal lines distributed in multiple metal layers, configured to achieve the designed connections. In the disclosed embodiments, the conductive features in the interconnect structure are distributed on the frontside and the backside of the substrate.

As described earlier, such as in FIG. 4A/4B or 6, the IC structure 100 includes a substrate having a frontside and a backside. Various features of the FETs, including gate structures and S/D features, are formed on the frontside of the substrate. However, those conductive features are designed to distribute on both the frontside and the backside of the substrate so to address various issues mentioned early, including the limitations to read and write speeds and the power consumption. More particularly, the IC structure 100 includes a frontside interconnect structure formed on the frontside of the substrate and a backside interconnect structure formed on the backside of the substrate. Various contacts and vias are properly distributed on the frontside interconnect structure and the backside interconnect structure according to various embodiments. In some alternative embodiments, some contacts and vias are formed on both frontside and backside of the substrate with redundancy and robustness, which also increase the read and write speeds and the circuit reliability.

FIGS. 7A and 7B are top views of the IC structure 100, in portion, constructed according to some embodiments. FIGS. 7A and 7B are similar to FIG. 3E but FIG. 7A illustrates contacts 312 and vias 314 (simply referred to as contacts 312F and vias 314F, respectively) formed on the frontside and FIG. 7B illustrates contacts 312 and vias 314 (simply referred to as contacts 312B and vias 314B) formed on the backside of the substrate. Various contacts 312 and vias 314 are distributed on the frontside and the backside of the substrate. Those contacts 312 are connected to write word line (WWL), write bit line (WBL), write bit line bar (WBLB), read bit line (RBL), read word line (RWL), power line (Vdd), and ground line (Vss or GND), respectively; and the vias 314 are connected to the corresponding contacts 312. When a contact 312 is formed on one side (such as the frontside or the backside), the corresponding via 314 is formed on the same side as well and is landing on that contact 312. The contacts 312 and vias 314 formed on the frontside are referred to as frontside contacts 312F and frontside vias 314F; and the contacts 312 and vias 314 formed on the backside are referred to as backside contacts 312B and backside vias 314B for clarification. In the disclosed embodiments, the write bit lines, such as WBL and WBLB are distributed on the backside of the substrate as illustrated in FIG. 7B. In furtherance of the embodiments, the contacts 312F and vias 314F associated with WWL, RWL, RBL, Vdd, and Vss are formed on the frontside of the substrate as illustrated in FIG. 7A. The contacts 312B and vias 314B associated with WBL, WBLB, and Vss are formed on the backside of the substrate as illustrated in FIG. 7B. Note that each SRAM cell 104 includes two Vss distributed on the frontside and the backside of the substrate. In some embodiments, the contacts 312F landing on the gate structures 310 may directly extend up to the metal lines without intervening vias. Accordingly, those contacts 312F landing the gate structures 310 are illustrated with different pattern in FIG. 7A and other subsequent figures. In some embodiments, a subset of the contacts 312F and a subset of the vias 314F are configured to collectively function as butted contacts, in which each butted contact connects a gate structure of one FET to a source/drain feature of an adjacent FET.

The metal lines 316 landing on and connected to the vias are further illustrated in FIGS. 7C and 7D according to some embodiments. FIGS. 7C and 7D are top views of the IC structure 100, in portion, constructed according to some embodiments. FIG. 7C is similar to FIG. 7A but further includes the metal lines 316 (also referred to as metal lines 316F) of the frontside interconnect structure; and FIG. 7D is similar to FIG. 7B but further includes the metal lines 316 (also referred to as metal lines 316B) of the backside interconnect structure.

By the disclosed configuration, WBL (and WBLB) and the corresponding contacts, vias and meal lines are relocated to the backside of the substrate, the dimensions (width and/or thickness) of the conductive features are increased, and the resistance is reduced. Accordingly, the write speed at minimum operation voltage (Wvmin) is increased and the power consumption is reduced. The RBL gains the freedom to rearrange so to increase the spacing between the adjacent metal lines, therefore the parasitic capacity and the corresponding RC delay are reduced, and the read speed is increased. The ground line Vss is supplied from dual sides (both frontside and backside) to reduce the resistance and increase the write and read speed, and reduce the power consumption. Other benefits may further present in the disclosed IC structure.

In an alternative embodiment, the dimensions of the metal lines 316F may be designed differently, such as one illustrated in FIG. 7E. FIG. 7E is a top view of the IC structure 100, in portion, constructed according to some embodiments. FIG. 7E is similar to FIG. 7C but the metal lines 316 may be designed with increased and/or different widths. In the disclosed embodiments, the metal line 316F connected to RBL has an increased width W1 while other metal lines 316F in the same metal layer of the frontside interconnect structure have a width Wf. W1 is greater than Wf. In some embodiments, the ratio W1/Wf ranges between 1.2 and 1.6. In some embodiments, the ratio W1/Wf ranges between 1.5 and 2.5. In the present embodiment, the metal line 316F connected to RBL is landing on the S/D via 314F, which is further landing on the corresponding S/D contact 312F. In some embodiments, the metal lines landing on the gate contacts 312F are either jumped to the metal lines in the second metal layer of the frontside interconnect structure or simply not shown for better view.

In another alternative embodiment, the dimensions of the metal lines 316B may be designed differently, such as one illustrated in FIG. 7F. FIG. 7F is a top view of the IC structure 100, in portion, constructed according to some embodiments. FIG. 7F is similar to FIG. 7D but the metal lines 316 may be designed with increased and/or different widths. In the disclosed embodiments, the metal lines 316B connected to WBL (and/or WBLB) have an increased width W2 while other metal lines 316B in the same metal layer of the backside interconnect structure have a width Wb. W2 is greater than Wb. In some embodiments, the ratio W2/Wb ranges between 1.2 and 1.6. In some embodiments, the ratio W2/Wb ranges between 1.5 and 2.5. In the present embodiment, the metal line 316B connected to WBL or WBLB is landing on the S/D via 314B, which is further landing on the corresponding S/D contact 312B.

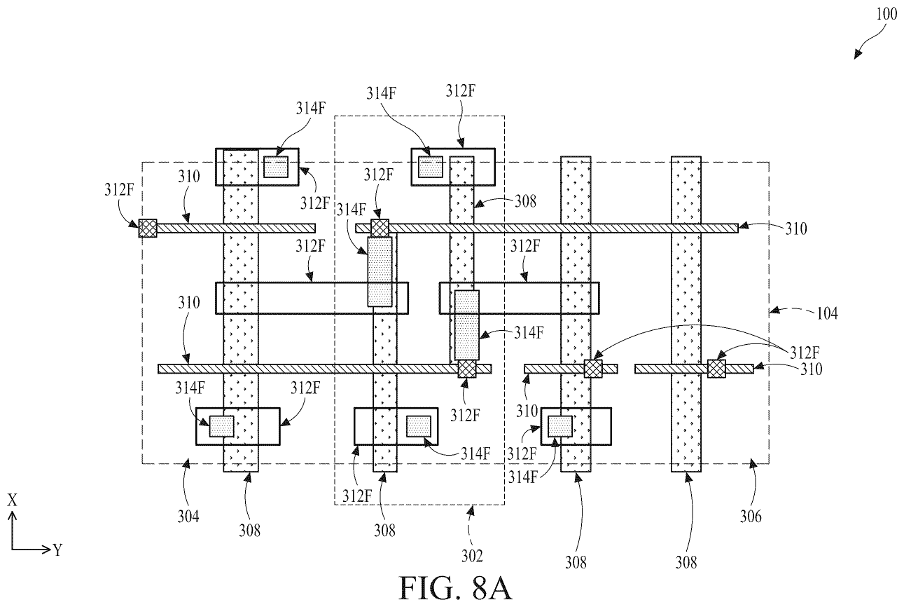

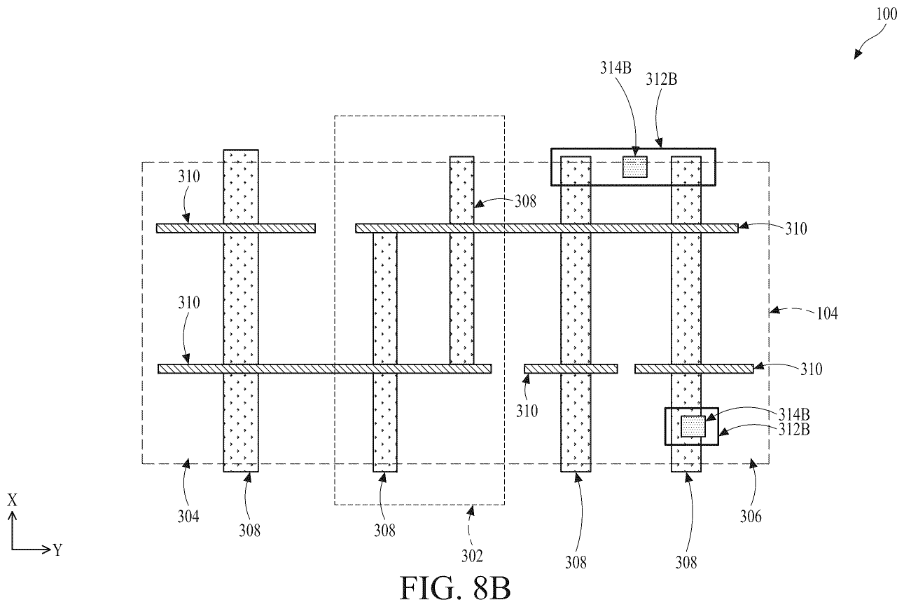

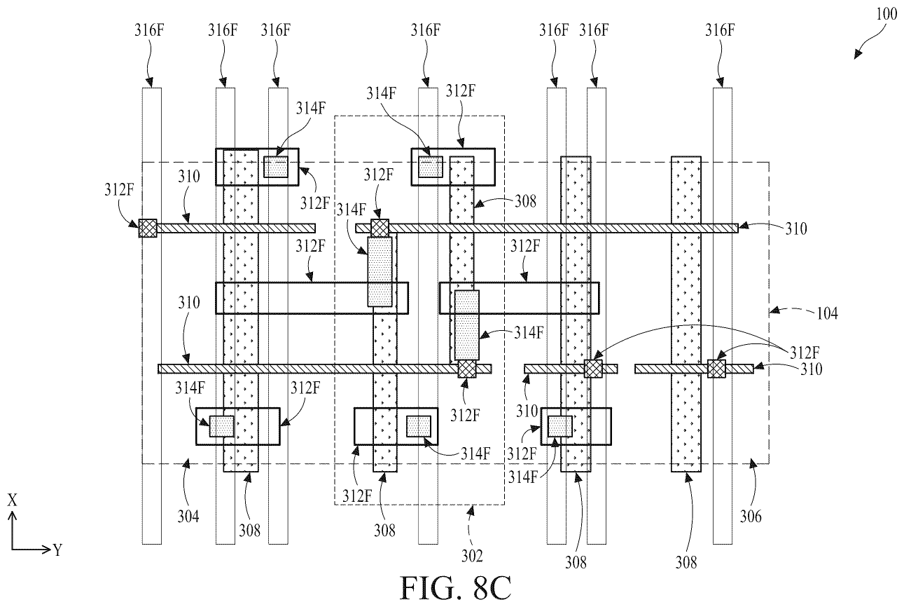

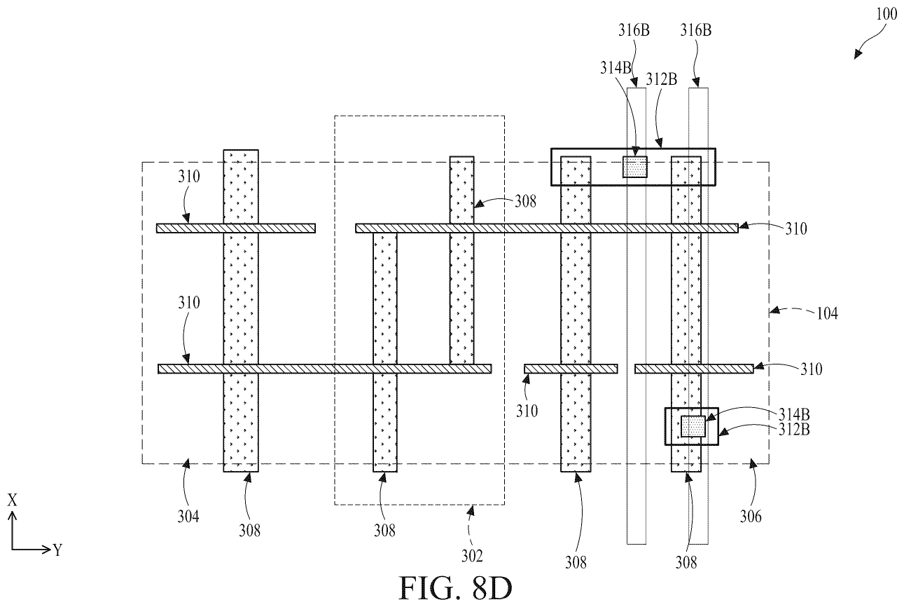

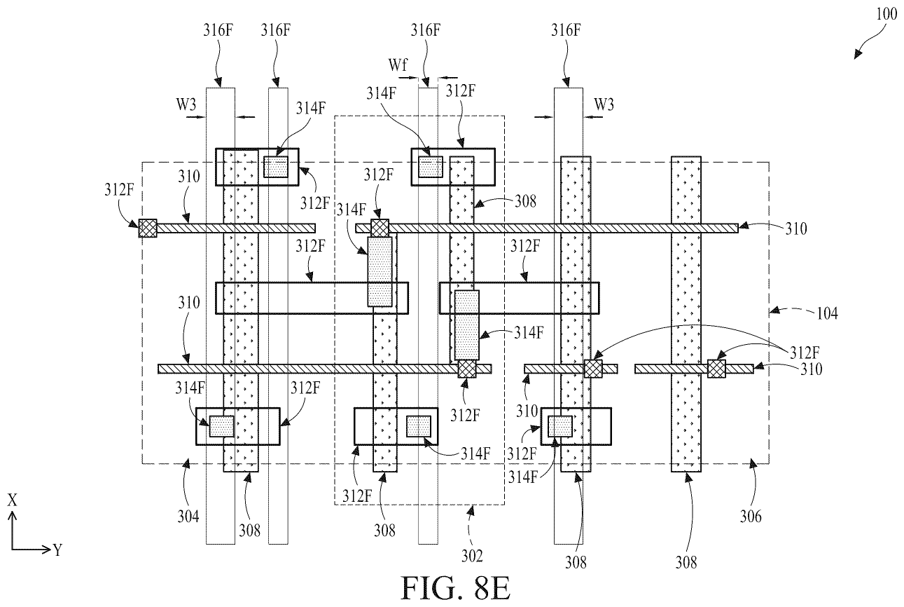

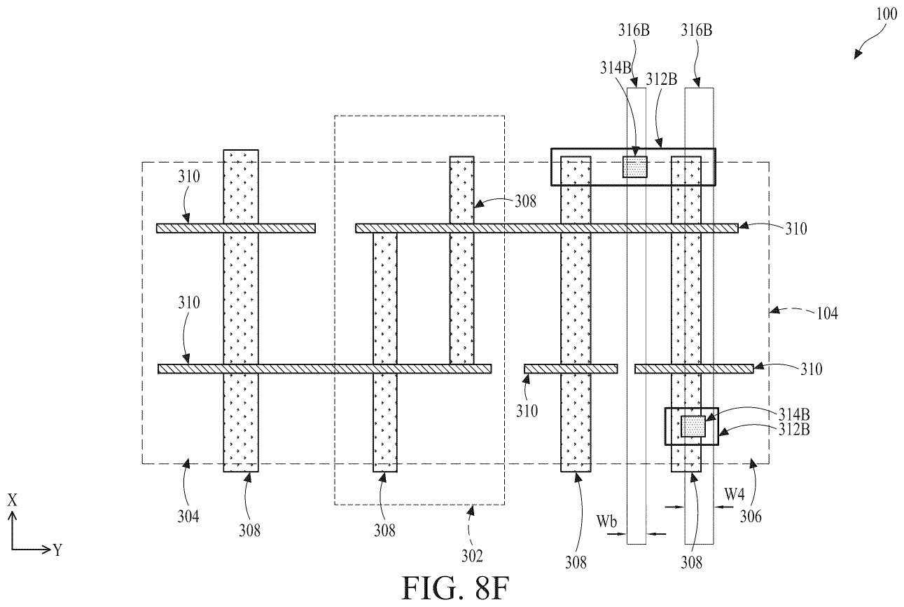

FIGS. 8A and 8B are top views of the IC structure 100, in portion, constructed according to some embodiments. FIGS. 8A and 8B are similar to FIG. 3B but FIG. 8A illustrates contacts 312 and vias 314 (simply referred to as contacts 312F and vias 314F, respectively) formed on the frontside and FIG. 8B illustrates contacts 312 and vias 314 (simply referred to as contacts 312B and vias 314B) formed on the backside of the substrate. FIGS. 8A and 8B are similar to FIGS. 7A and 7B but with different distributions of those contacts 312 and vias 314 on the frontside and the backside of the substrate. Various contacts 312 and vias 314 are distributed on the frontside and the backside of the substrate. Those contacts 312 are connected to write word line (WWL), write bit line (WBL), write bit line bar (WBLB), read bit line (RBL), read word line (RWL), power line (Vdd), and ground line (Vss or GND), respectively; and the vias 314 are connected to the corresponding contacts 312. When a contact 312 is formed on one side (such as the frontside or the backside), the corresponding via 314 is formed on the same side as well and is landing on that contact 312. The contacts 312 and vias 314 formed on the frontside are referred to as frontside contacts 312F and frontside vias 314F; and the contacts 312 and vias 314 formed on the backside are referred to as backside contacts 312B and backside vias 314B for clarification. In the disclosed embodiments, the read bit lines (RBL) are distributed on the backside of the substrate as illustrated in FIG. 8B. In furtherance of the embodiments, the contacts 312F and vias 314F associated with WWL, WBL, RWL, Vdd, and Vss are formed on the frontside of the substrate as illustrated in FIG. 8A. The contacts 312B and vias 314B associated with RBL and Vss are formed on the backside of the substrate as illustrated in FIG. 8B. Note that each SRAM cell 104 includes two Vss distributed on the frontside and the backside of the substrate.

The metal lines 316 landing on and connected to the vias are further illustrated in FIGS. 8C and 8D according to some embodiments. FIGS. 8C and 8D are top views of the IC structure 100, in portion, constructed according to some embodiments. FIG. 8C is similar to FIG. 8A but further includes the metal lines 316 (also referred to as metal lines 316F) of the frontside interconnect structure; and FIG. 8D is similar to FIG. 8B but further includes the metal lines 316 (also referred to as metal lines 316B) of the backside interconnect structure.

In an alternative embodiment, the dimensions of the metal lines 316F may be designed differently, such as one illustrated in FIG. 8E. FIG. 8E is a top view of the IC structure 100, in portion, constructed according to some embodiments. FIG. 8E is similar to FIG. 8C but the metal lines 316 may be designed with increased and/or different widths. In the disclosed embodiments, the metal lines 316F connected to WBLB (and/or WL B) have an increased width W3 while other metal lines 316F in the same metal layer of the frontside interconnect structure have a width Wf. W3 is greater than Wf. In some embodiments, the ratio W3/Wf ranges between 1.2 and 1.6. In some embodiments, the ratio W3/Wf ranges between 1.5 and 2.5. In the present embodiment, the metal line 316F connected to WBLB (or WLB) is landing on the S/D via 314F, which is further landing on the corresponding S/D contact 312F. In some embodiments, the metal lines landing on the gate contacts 312F are either jumped to the metal lines in the second metal layer of the frontside interconnect structure or simply not shown for better view.

In another alternative embodiment, the dimensions of the metal lines 316B may be designed differently, such as one illustrated in FIG. 8F. FIG. 78F is a top view of the IC structure 100, in portion, constructed according to some embodiments. FIG. 8F is similar to FIG. 8D but the metal lines 316 may be designed with increased and/or different widths. In the disclosed embodiments, the metal lines 316B connected to RBL have an increased width W4 while other metal lines 316B in the same metal layer of the backside interconnect structure have a width Wb. W4 is greater than Wb. In some embodiments, the ratio W4/Wb ranges between 1.2 and 1.6. In some embodiments, the ratio W4/Wb ranges between 1.5 and 2.5. In the present embodiment, the metal line 316B connected to RBL is landing on the S/D via 314B, which is further landing on the corresponding S/D contact 312B.

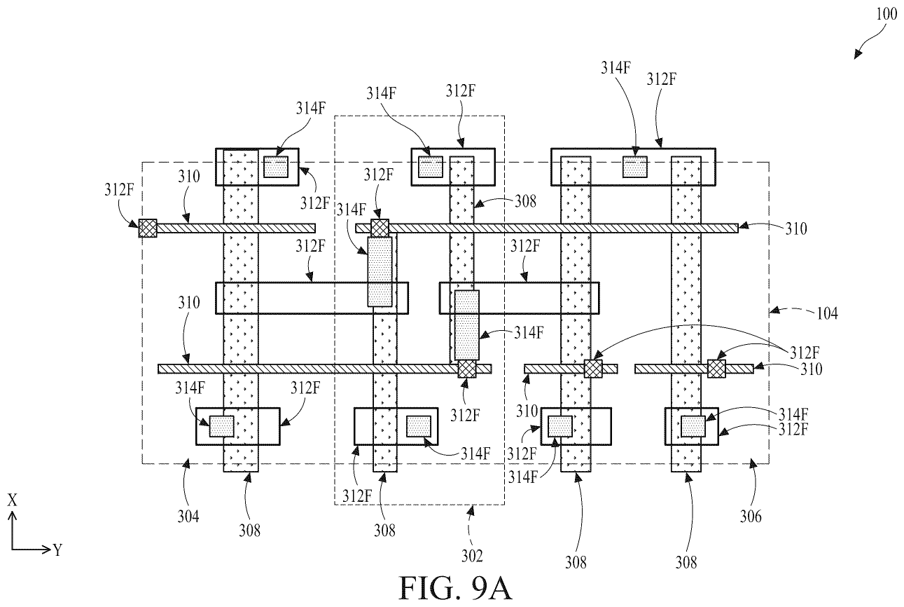

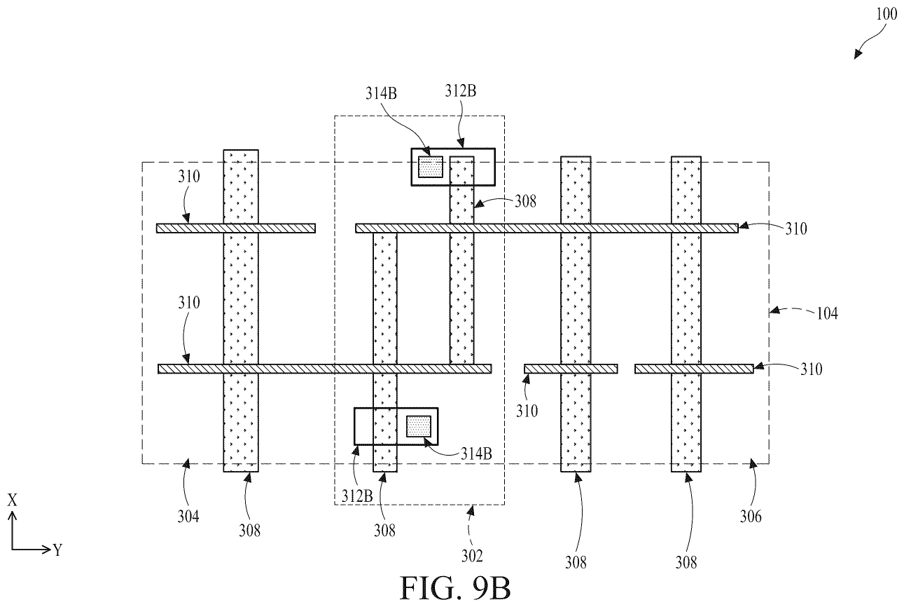

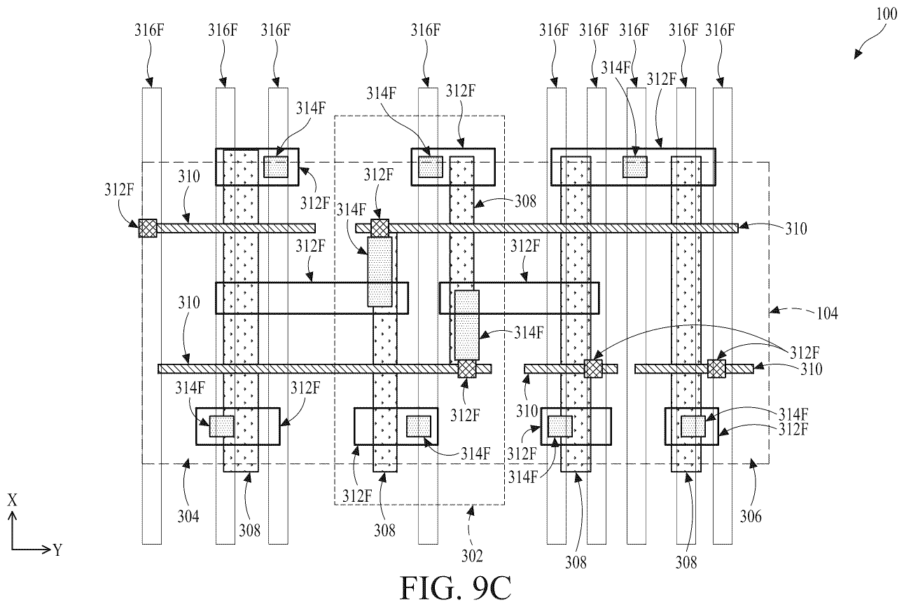

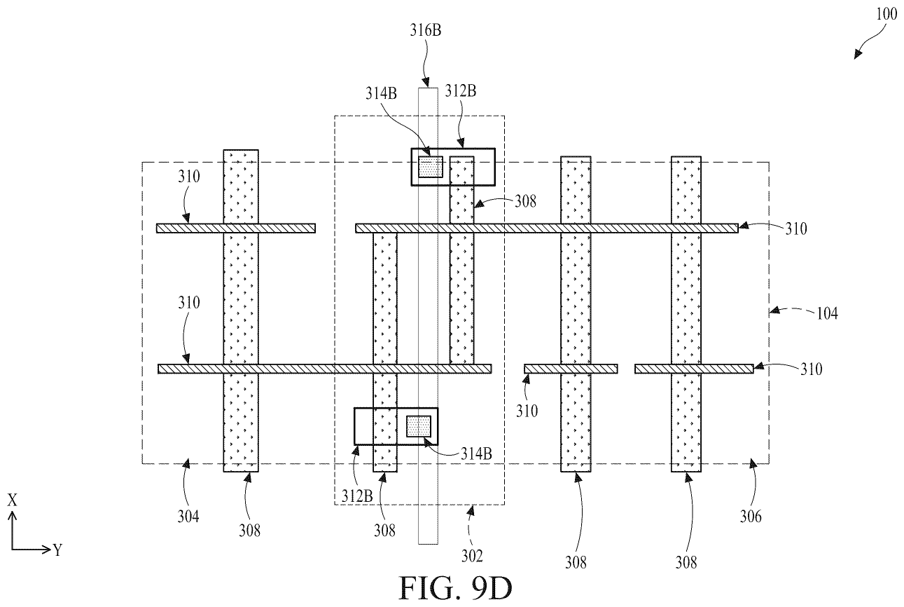

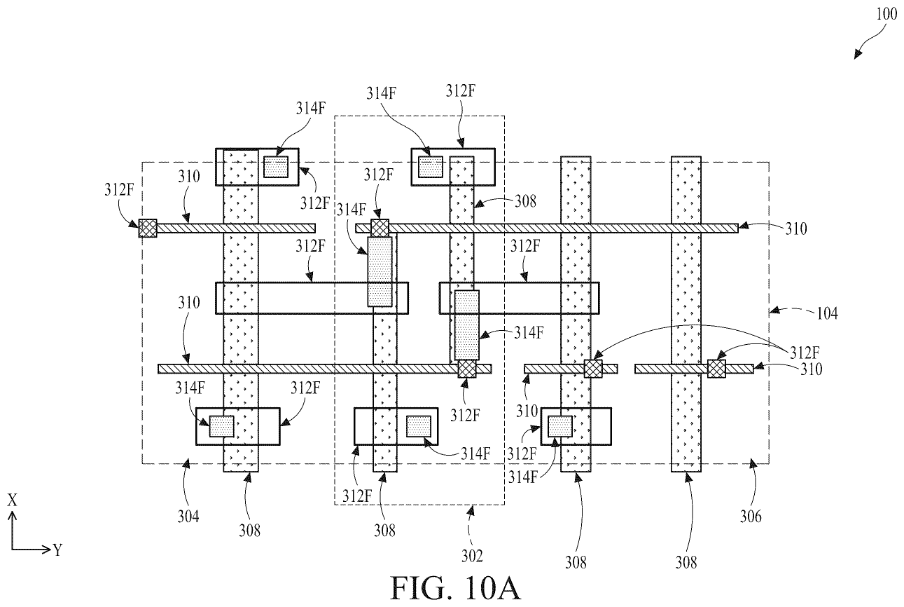

FIGS. 9A and 9B are top views of the IC structure 100, in portion, constructed according to some embodiments. FIGS. 9A and 9B are similar to FIG. 3B but FIG. 9A illustrates contacts 312 and vias 314 (simply referred to as contacts 312F and vias 314F, respectively) formed on the frontside and FIG. 9B illustrates contacts 312 and vias 314 (simply referred to as contacts 312B and vias 314B) formed on the backside of the substrate. FIGS. 9A and 9B are similar to FIG. 7A and 7B but with different distributions of those contacts 312 and vias 314 on the frontside and the backside of the substrate. Various contacts 312 and vias 314 are distributed on the frontside and the backside of the substrate. Those contacts 312 are connected to write word line (WWL), write bit line (WBL), write bit line bar (WBLB), read bit line (RBL), read word line (RWL), power line (Vdd), and ground line (Vss or GND), respectively; and the vias 314 are connected to the corresponding contacts 312. When a contact 312 is formed on one side (such as the frontside or the backside), the corresponding via 314 is formed on the same side as well and is landing on that contact 312. The contacts 312 and vias 314 formed on the frontside are referred to as frontside contacts 312F and frontside vias 314F; and the contacts 312 and vias 314 formed on the backside are referred to as backside contacts 312B and backside vias 314B for clarification. In the disclosed embodiments, the power lines (Vdd) are distributed on the frontside and the backside of the substrate. In furtherance of the embodiments, Vdd is supplied to each SRAM cell 104 from dual sides (backside and frontside of the substrate) as illustrated in FIGS. 9A and 9B. The contacts 312F and vias 314F associated with WWL, WBL, WBLB, RBL, RWL, Vdd, and Vss are formed on the frontside of the substrate as illustrated in FIG. 9A. The contacts 312B and vias 314B associated with Vdd are formed on the backside of the substrate as illustrated in FIG. 9B.

The metal lines 316 landing on and connected to the vias are further illustrated in FIGS. 9C and 9D according to some embodiments. FIGS. 9C and 9D are top views of the IC structure 100, in portion, constructed according to some embodiments. FIG. 9C is similar to FIG. 9A but further includes the metal lines 316 (also referred to as metal lines 316F) of the frontside interconnect structure; and FIG. 9D is similar to FIG. 9B but further includes the metal lines 316 (also referred to as metal lines 316B) of the backside interconnect structure. In an alternative embodiment, the dimensions of the metal lines 316F may be designed differently, such as those illustrated in FIG. 7E or 8E. Similar descriptions are not repeated here for simplicity.

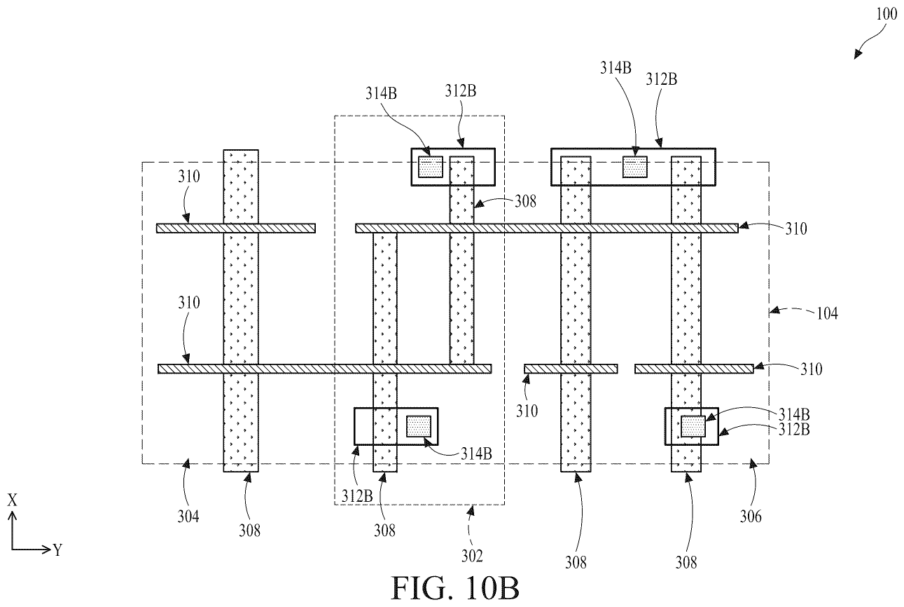

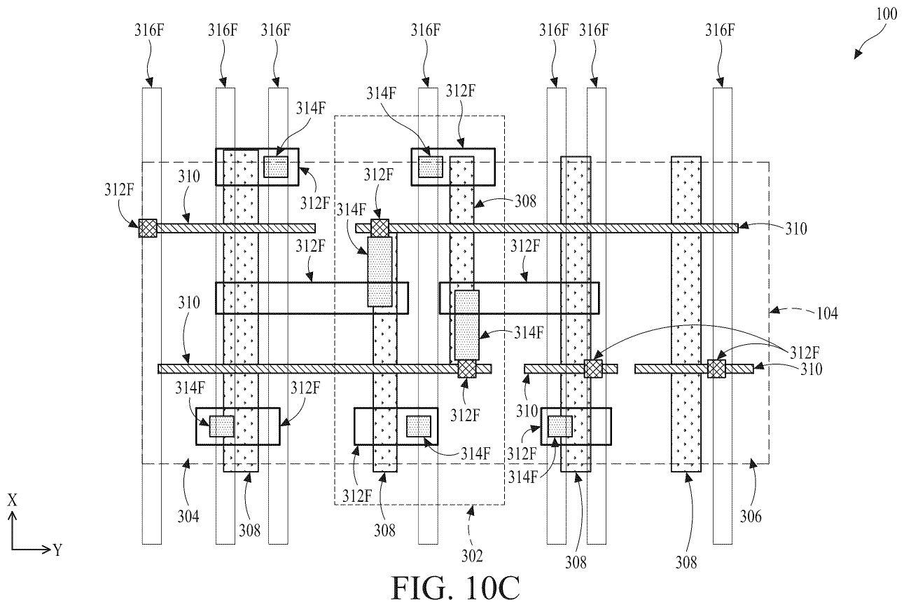

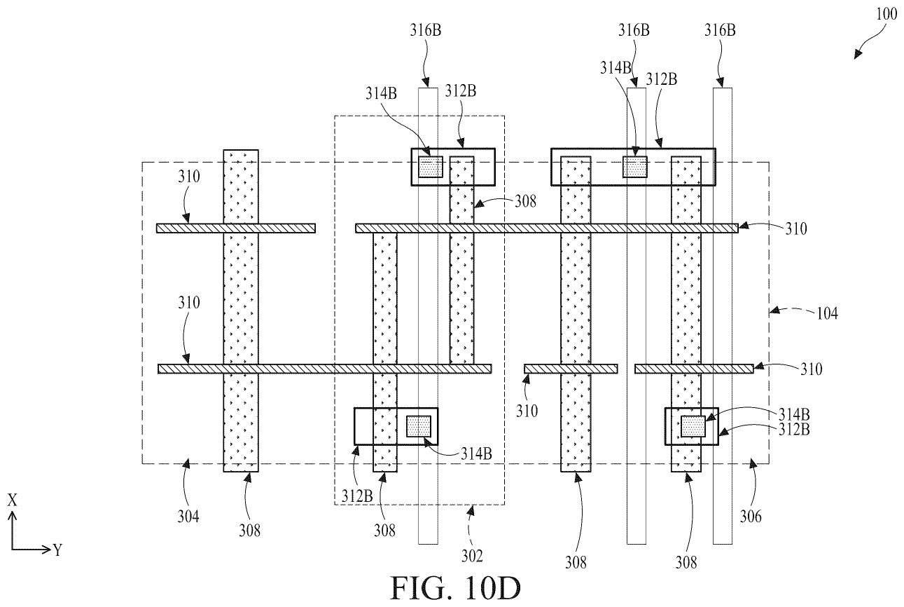

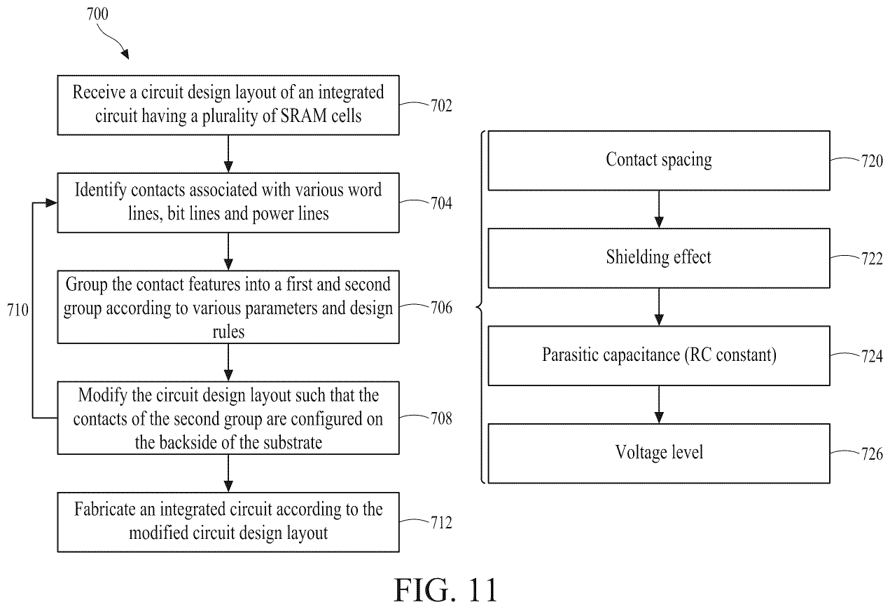

In some other embodiments, the distribution of Vdd in FIGS. 9A through 9D may be combined with distributions of other signal lines and power lines described above in various embodiments, such as those in FIG. 7A through 7D or 8A through 8D. For example, Vss is also distributed on dual sides; and RBL is moved to the backside, as illustrated in FIGS. 10A through 10D. FIGS. 10A and 10B are top views of the IC structure 100, in portion, constructed according to some embodiments. FIGS. 10C and 10D are top views of the IC structure 100, in portion, constructed according to some embodiments. FIG. 10C is similar to FIG. 10A but further includes the metal lines 316 (also referred to as metal lines 316F) of the frontside interconnect structure; and FIG. 10D is similar to FIG. 10B but further includes the metal lines 316 (also referred to as metal lines 316B) of the backside interconnect structure. In an alternative embodiment, the dimensions of the metal lines 316F may be designed differently, such as those illustrated in FIG. 7E or 8E. Similar descriptions are not repeated here for simplicity.

As described above, those power lines (Vdd and Vss) and signal lines (WBL, WBLB, WWL, RWL and RBL) are not all formed on the frontside of the integrated circuit structure 100 but are distributed on both the frontside and backside of the integrated circuit structure 100. Especially, the integrated circuit structure 100 includes a frontside interconnect structure and a backside interconnect structure disposed on the frontside and backside of the integrated circuit structure 100 respectively and configured to connect various components of the pull-up devices (PGs), pull-down devices (PDs), pass-gate devices (PGs), read pull-down device (RPD), read pass gate device (RPG) to form SRAM bit cells 104. The configuration is designed with considerations of various factors and parameters, including sizes of various conductive features, packing density, resistance of the conductive features, parasitic capacitances among adjacent conductive features, overlay shifting and processing margins. For example, if conductive features are too close, overlay shift may lead to short and leakage issues; the sizes of the conductive features are reduced, leading to increased resistances; the parasitic capacitances are increased as well; the processing margins are reduced; and so on. If the sizes of the conductive features are increased, the resistances of the conductive features are reduced but the spacing between the adjacent conductive features are decreased, leading to the increased parasitic capacitances, and reduced processing margins. If shielding conductive features are placed among adjacent conductive features, the parasitic capacitances are reduced. However, the packing density is reduced, and/or the resistances of the conductive features are increased. Accordingly, the power lines and signal lines are distributed on both the frontside and the backside of the substrate.

The present disclosure may include other embodiments, variations and/or alternations. In some other embodiments, WWL may have dual ports distributed on the frontside and the backside of the substrate. In some embodiments, the SRAM bit cells 104 may be constructed with an asymmetric layout to achieve various advantages, such as more uniform pattern density, more uniform metal line spacing, and accordingly more reduced parasitic capacity, higher current and enhanced speed. This is because those SRAM bits cells 104 are configured next to each other in an array and adjacent cells may share common power lines or signal lines continuing multiple SRAM cells. Some embodiments are described below. In some embodiments, one SRAM cell 104 adopts a layout described in FIG. 7A through 7D (or 7E and 7F) while an adjacent SRAM cell 104 adopts a layout described in FIG. 8A through 8D (or 8E and 8F). In furtherance of the embodiment, the two adjacent SRAM cells 104 are configured next each other along Y direction, such as those shown in FIG. 3C. The array of the SRAM cells 104 may repeat this alternative structure along Y direction. In some other embodiments, one SRAM cell 104 adopts a layout described in FIG. 7A through 7D (or 7E and 7F) while an adjacent SRAM cell 104 adopts a layout described in FIGS. 10A through 10D. Additional cells may be configured in cascade with similar asymmetric configuration. In some embodiments, the power lines Vdd for adjacent SRAM cells are also designed asymmetrically, such as Vdd in one cell is formed on the frontside and Vdd in an adjacent cell is backside of the substrate.

Other asymmetric layouts are contemplated by the present disclosure. A method of generating an integrated circuit structure having SRAM cells with an asymmetric layout (such as those described above) is provided below in detail. FIG. 11 is a flowchart of a method 700 constructed according to some embodiments.

At block 702 of the method 700, a layout of an integrated circuit having a plurality of SRAM cells 104 is received as an initial layout. In the initial layout, various bit-lines (WBL, WBLB and RBL), word-lines (WWL and RWL), and power lines (Vss and Vdd) are configured on the frontside of substrate. At block 704, contact features associated with various bit-lines (WBL, WBLB and RBL), word-lines (WWL and RWL), and power lines (Vss and Vdd) are identified in each SRAM cell 104. At block 706, the identified contact features in a SRAM cell 104 are classified into two groups: a first group and a second group according to relevant parameters (such as contact resistance, and RC constant) and design rules (such as contact spacing, shielding effect, RC constant, read speed, write speed, and other relevant factors, such as those further described below in detail. At block 708, the layout of the SRAM cell in the integrated circuit is modified such that the first group of contacts and corresponding conductive features (i.e., via features and metal lines) are configured on the frontside of the substrate and the first group of contacts and corresponding conductive features are configured on the frontside of the substrate. At block 710, this process is an iterative process according to various factors (such as those described above) until the layout in the SRAM cell optimized. Block 710 also repeat such process for other SRAM cells 104. For example, after a first SRAM cell 104 is processed, an adjacent SRAM cell is processed similarly, especially, the adjacent SRAM cell 104 is processed according to the same factors and additionally the effect of the interaction between the adjacent SRAM cells. Particularly, those factors are evaluated for the first SRAM cell in the intercell, and those factors are evaluated for the second (adjacent) SRAM cell both in intercell and intracell. For example, the first SRAM cell has the WBLB configured on the backside while the second SRAM cell has the complimentary WBLB configured on the frontside according intercell effect and intracell effect since WB L Bs in the first and second cell are further distanced to reduce the crosstalk. When the process continues to other SRAM cells, it may have multiple adjacent cells and needs to consider intracell effects to multiple adjacent cells. The method 700 may also include a block 712, in which the integrated circuit is fabricated according to the modified layout. For example, various photomasks are made according to the modified layout and integrated circuits are fabricated on semiconductor substrates using the photomasks.

Referring back to block 706 to classify the contacts into the first and second groups, various factors are considered. Those factors may be evaluated sequentially according to impact significance of those factors. In one embodiment illustrated in FIG. 11, various factors are considered sequentially according to factors at blocks 720 through 726. At block 720, the design rule, such as contact spacing, is first considered. Those contacts having too narrow spacings or in violation with design rule are considered to classified to different groups (such as one in the first group and another in the second group). Thus, contact spacing can be increased, the contact size can also be increased, and contact resistance can be reduced.

At block 722, the shielding effect or crosstalk is considered. The crosstalk refers to undesired signal transfer between single lines. For example, WBL and WBLB may carry different signals and interaction between these two signal lines are undesired. In this case, WBL and WBLB are classified to different group. At present step, when WBL and WBLB distributed to different group can also substantially reduce the contact spacing, instead of redistributing other two contact features (such as Vss and Vdd), WBL and WBLB are redistributed to the backside and the frontside, respectively.

At block 724, a parasitic capacitance and RC constant are considered. The parasitic capacitance between conductive features impact RC constant and the circuit speed. Circuit speed is evaluated at this step. The grouping may be further adjusted according to the circuit speed requirements. For example, if a grouping strategy can substantially improve the circuit speed or effectively tune a local speed according to the circuit specification without substantially impacting other factors (such as contact spacing and shielding effect), the layout is modified accordingly.

At block 726, the voltage levels of power lines may be considered as one effect to form the two groups for redistribution on the frontside and backside of the substrate. When the grouping still has freedom for further adjustment, power lines with different voltage levels can be a factor for further tuning to grouping. For example, Vss and Vdd in a same cell or in adjacent cells may be classified to different groups. Accordingly, high voltage power line (Vdd) and low (grounding) power line (Vss) interaction can be reduced.

The method 700 is described above according to some embodiments. However, these factors may be evaluated in a different sequence (such as shielding effect, then contact spacing, RC constant and power lines) or some factors may be collectively evaluated (such as parasitic capacitance and contact spacing). Other factors may be alternatively or additionally considered. For example, shared word-lines or overlay shift. In furtherance of the example, some contact features or corresponding conductive features are fabricated using different photomasks, the overlay shift is an additional factor to be evaluated according to the overlay shift margin.

A method 730 of making the IC structure 100 is described according to some embodiments. Especially, the method includes forming an IC structure that includes field effect transistors (FETs) having nanosheets or nanotubes with multiple channels vertically stacked, multiple gate structure, and backside interconnect structure including backside contacts. An IC structure 800 at various fabrication stages are provided to further illustrate the method 730 but is not intended to be limiting. For example, the method 730 is also able to make the IC structure 100 having SRAM devices or other proper IC structures.

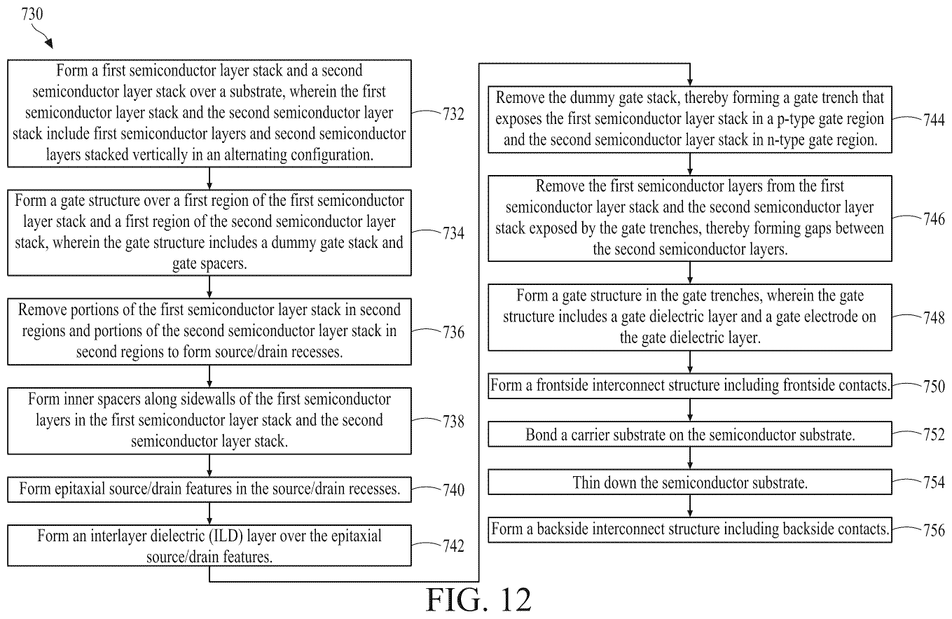

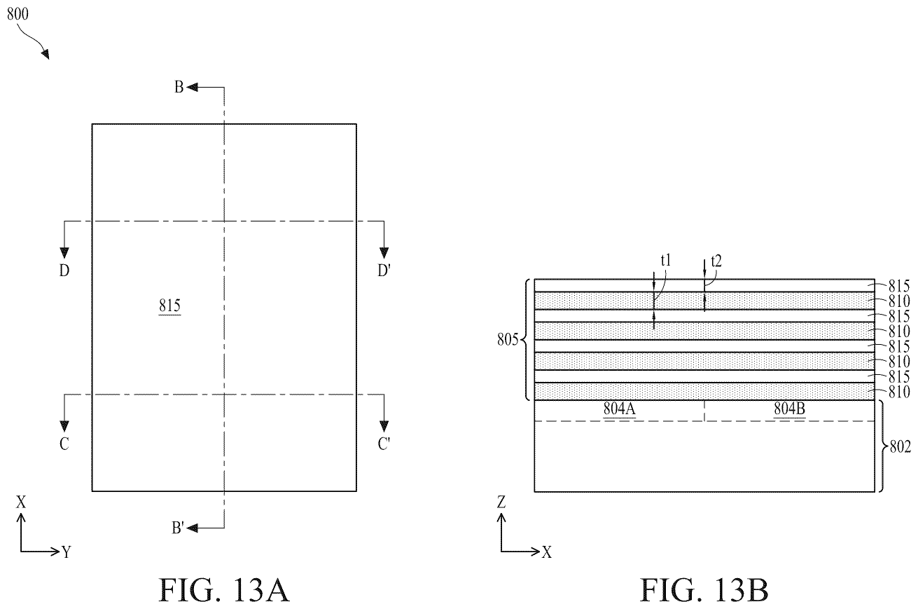

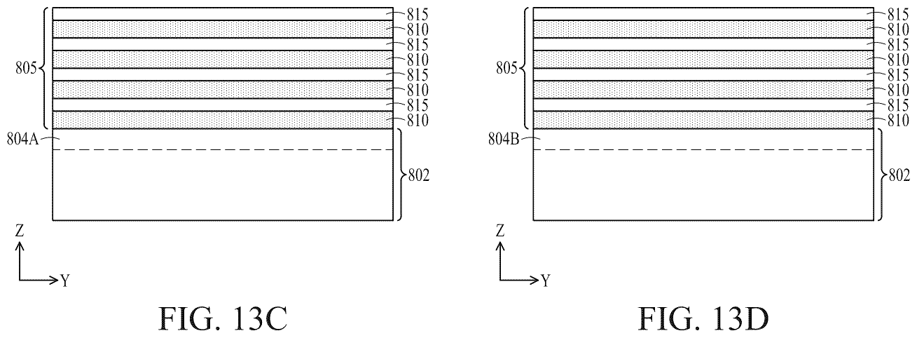

FIG. 12 is a flowchart of the method 730 for fabricating an IC structure according to various aspects of the present disclosure. FIGS. 13A-23A, FIGS. 13B-23B, FIGS. 13C-23C, FIGS. 13D-23D, and FIGS. 24-27 are fragmentary diagrammatic views of an IC structure 800, in portion or entirety, at various fabrication stages (such as those associated with the method in FIG. 12) according to various aspects of the present disclosure.

In some embodiments, method 730 fabricates the IC structure 800 that includes p-type GAA transistors and n-type GAA transistors. At block 732, a first semiconductor layer stack and a second semiconductor layer stack are formed over a substrate. The first semiconductor layer stack and the second semiconductor layer stack include first semiconductor layers and second semiconductor layers stacked vertically in an alternating configuration. At block 734, a gate structure is formed over a first region of the first semiconductor layer stack and a first region of the second semiconductor layer stack. The gate structure includes a dummy gate stack and gate spacers. At block 736, portions of the first semiconductor layer stack in second regions and portions of the second semiconductor layer stack in second regions are removed to form source/drain recesses. At block 738, inner spacers are formed along sidewalls of the first semiconductor layers in the first semiconductor layer stack and the second semiconductor layer stack. At block 740, epitaxial source/drain features are formed in the source/drain recesses. At block 742, an interlayer dielectric (ILD) layer is formed over the epitaxial source/drain features. At block 744, the dummy gate stack is removed, thereby forming a gate trench that exposes the first semiconductor layer stack in a p-type gate region and the second semiconductor layer stack in n-type gate region. At block 746, the first semiconductor layers are removed from the first semiconductor layer stack and the second semiconductor layer stack exposed by the gate trenches, thereby forming gaps between the second semiconductor layers. At block 748, gate structures are formed in the gate trenches around the second semiconductor layers in the p-type gate region and the n-type gate region. A gate structure includes a dielectric layer and a gate electrode on the gate dielectric layer. At block 750, a frontside interconnect structure is formed on the gate structures and source/drain features to couple various field-effect transistors and other devices into an integrated circuit. The frontside interconnect structure includes contacts, vias and metal lines disposed on the frontside of the semiconductor substrate. At block 752, a carrier substrate is bonded to the frontside of the semiconductor substrate. At block 754, a backside of the semiconductor substrate is thin down. At block 756, a backside interconnect structure is formed on the backside of the semiconductor substrate. The backside interconnect structure includes contacts and may further include vias and metal lines.

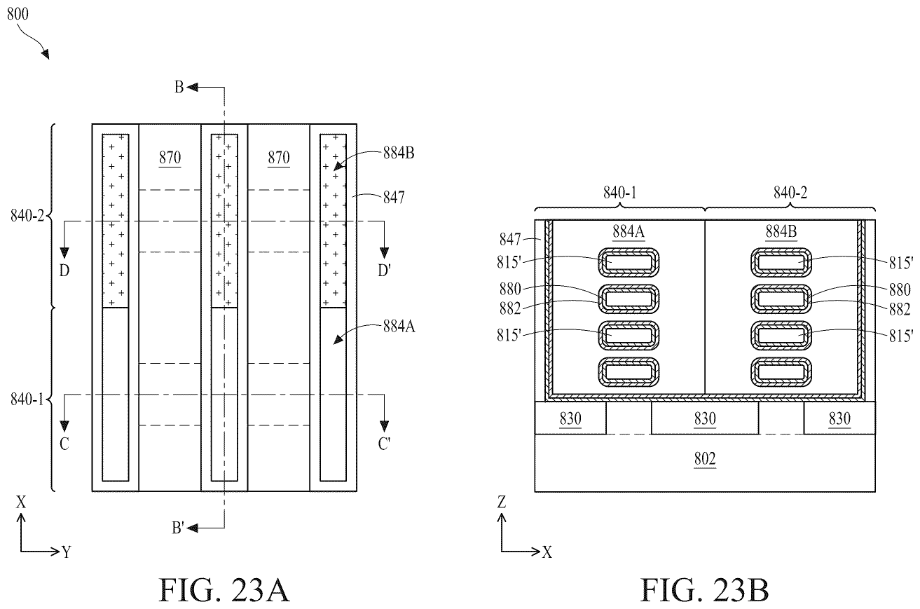

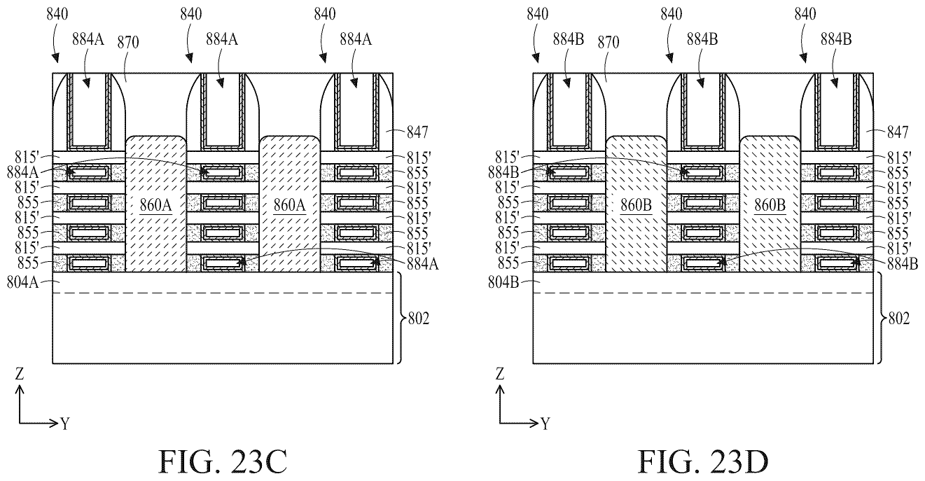

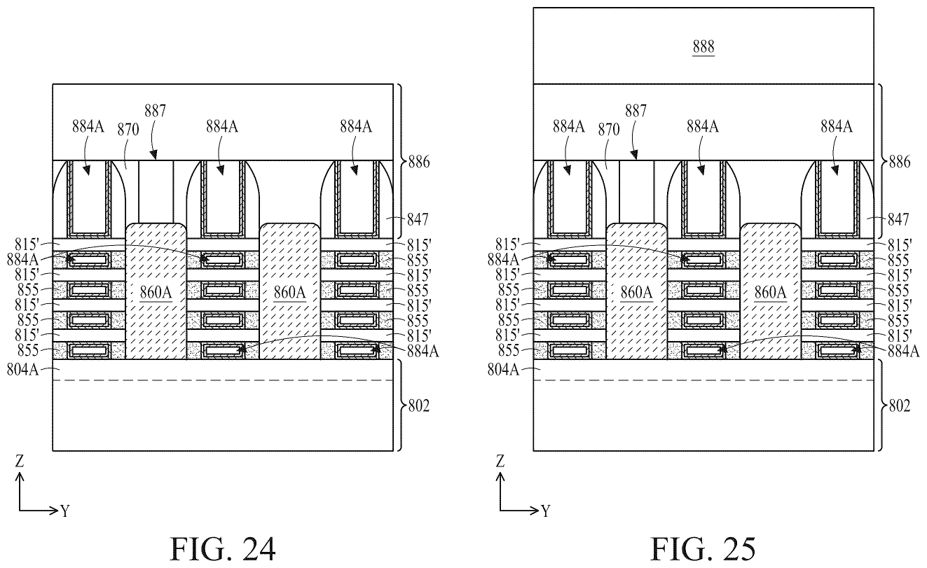

FIGS. 13A-23A, FIGS. 13B-22B, FIGS. 13C-23C, FIGS. 13D-23D, and FIGS. 24-27 are fragmentary diagrammatic views of an integrated circuit (IC) structure 800, in portion or entirety, at various fabrication stages (such as those associated with method 100 in FIG. 1) according to various aspects of the present disclosure. In particular, FIGS. 13A-23A are top views of IC structure 800 in an X-Y plane; FIGS. 13B-23B are diagrammatic cross-sectional views of IC structure 800 in an X-Z plane along lines B-B′ respectively of FIGS. 13A-23A, FIGS. 13C-23C are diagrammatic cross-sectional views of IC structure 800 in a Y-Z plane along lines C-C′ respectively of FIGS. 13A-23A; and FIGS. 13D-23D are diagrammatic cross-sectional views of IC structure 800 in the Y-Z plane along lines D-D′ respectively of FIGS. 13A-23A. FIGS. 24-27 are diagrammatic cross-sectional views of IC structure 800 in a Y-Z plane along lines C-C′ of FIG. 23A but at different fabrication stages. IC structure 800 may be included in a microprocessor, a memory, and/or other IC device. In some embodiments, IC structure 800 is a portion of an IC chip, a system on chip (SoC), or portion thereof, that includes various passive and active microelectronic devices such as resistors, capacitors, inductors, diodes, p-type field effect transistors (PFETs), n-type field effect transistors (NFETs), metal-oxide semiconductor field effect transistors (MOSFETs), complementary metal-oxide semiconductor (CMOS) transistors, bipolar junction transistors (BJTs), laterally diffused MOS (LDMOS) transistors, high voltage transistors, high frequency transistors, other suitable components, or combinations thereof. In some embodiments, IC structure 800 is included in a non-volatile memory, such as a non-volatile random-access memory (NVRAM), a flash memory, an electrically erasable programmable read only memory (EEPROM), an electrically programmable read-only memory (EPROM), other suitable memory type, or combinations thereof. FIGS. 13A-23A, FIGS. 13B-23B, FIGS. 13C-23C, FIGS. 13D-23D, and FIGS. 24-27 have been simplified for the sake of clarity to better understand the inventive concepts of the present disclosure. Additional features can be added in IC structure 800, and some of the features described below can be replaced, modified, or eliminated in other embodiments of IC structure 800.

Turning to FIGS. 13A-13D, IC structure 800 includes a substrate (wafer) 802. In the depicted embodiment, substrate 802 includes silicon. Alternatively or additionally, substrate 802 includes another elementary semiconductor, such as germanium; a compound semiconductor, such as silicon carbide, gallium arsenide, gallium phosphide, indium phosphide, indium arsenide, and/or indium antimonide; an alloy semiconductor, such as silicon germanium (SiGe), GaAsP, AlInAs, AlGaAs, GaInAs, GaInP, and/or GaInAsP; or combinations thereof. Alternatively, substrate 802 is a semiconductor-on-insulator substrate, such as a silicon-on-insulator (SOI) substrate, a silicon germanium-on-insulator (SGOI) substrate, or a germanium-on-insulator (GOI) substrate. Semiconductor-on-insulator substrates can be fabricated using separation by implantation of oxygen (SIM OX), wafer bonding, and/or other suitable methods. Substrate 802 can include various doped regions depending on design requirements of IC structure 800. In the depicted embodiment, substrate 802 includes a p-type doped region 804A (referred to hereinafter as a p-well), which can be configured for n-type GA A transistors, and an n-type doped region 804B (referred to hereinafter as an n-well), which can be configured for p-type GAA transistors. N-type doped regions, such as n-well 804B, are doped with n-type dopants, such as phosphorus, arsenic, other n-type dopant, or combinations thereof. P-type doped regions, such as p-well 804A, are doped with p-type dopants, such as boron, indium, other p-type dopant, or combinations thereof. In some implementations, substrate 802 includes doped regions formed with a combination of p-type dopants and n-type dopants. The various doped regions can be formed directly on and/or in substrate 802, for example, providing a p-well structure, an n-well structure, a dual-well structure, a raised structure, or combinations thereof. An ion implantation process, a diffusion process, and/or other suitable doping process can be performed to form the various doped regions.

A semiconductor layer stack 805 is formed over substrate 802, where semiconductor layer stack 805 includes semiconductor layers 810 and semiconductor layers 815 stacked vertically (e.g., along the z-direction) in an interleaving or alternating configuration from a surface of substrate 802. In some embodiments, semiconductor layers 810 and semiconductor layers 815 are epitaxially grown in the depicted interleaving and alternating configuration. For example, a first one of semiconductor layers 810 is epitaxially grown on substrate, a first one of semiconductor layers 815 is epitaxially grown on the first one of semiconductor layers 815, a second one of semiconductor layers 810 is epitaxially grown on the first one of semiconductor layers 815, and so on until semiconductor layers stack 805 has a desired number of semiconductor layers 810 and semiconductor layers 815. In such embodiments, semiconductor layers 810 and semiconductor layers 815 can be referred to as epitaxial layers. In some embodiments, epitaxial growth of semiconductor layers 810 and semiconductor layers 815 is achieved by a molecular beam epitaxy (MBE) process, a chemical vapor deposition (CVD) process, a metalorganic chemical vapor deposition (MOCVD) process, other suitable epitaxial growth process, or combinations thereof.

A composition of semiconductor layers 810 is different than a composition of semiconductor layers 815 to achieve etching selectivity and/or different oxidation rates during subsequent processing. In some embodiments, semiconductor layers 810 have a first etch rate to an etchant and semiconductor layers 815 have a second etch rate to the etchant, where the second etch rate is less than the first etch rate. In some embodiments, semiconductor layers 810 have a first oxidation rate and semiconductor layers 815 have a second oxidation rate, where the second oxidation rate is less than the first oxidation rate. In the depicted embodiment, semiconductor layers 810 and semiconductor layers 815 include different materials, constituent atomic percentages, constituent weight percentages, thicknesses, and/or characteristics to achieve desired etching selectivity during an etching process, such as an etching process implemented to form suspended channel layers in channel regions of IC structure 800. For example, where semiconductor layers 810 include silicon germanium and semiconductor layers 815 include silicon, a silicon etch rate of semiconductor layers 815 is less than a silicon germanium etch rate of semiconductor layers 810. In some embodiments, semiconductor layers 810 and semiconductor layers 815 can include the same material but with different constituent atomic percentages to achieve the etching selectivity and/or different oxidation rates. For example, semiconductor layers 810 and semiconductor layers 815 can include silicon germanium, where semiconductor layers 810 have a first silicon atomic percent and/or a first germanium atomic percent and semiconductor layers 815 have a second, different silicon atomic percent and/or a second, different germanium atomic percent. The present disclosure contemplates that semiconductor layers 810 and semiconductor layers 815 include any combination of semiconductor materials that can provide desired etching selectivity, desired oxidation rate differences, and/or desired performance characteristics (e.g., materials that maximize current flow), including any of the semiconductor materials disclosed herein.

As described further below, semiconductor layers 815 or portions thereof form channel regions of IC structure 800. In the depicted embodiment, semiconductor layer stack 805 includes four semiconductor layers 810 and four semiconductor layers 815 configured to form four semiconductor layer pairs disposed over substrate 802, each semiconductor layer pair having a respective first semiconductor layer 810 and a respective second semiconductor layer 815. After undergoing subsequent processing, such configuration will result in IC structure 800 having four channels. However, the present disclosure contemplates embodiments where semiconductor layer stack 805 includes more or less semiconductor layers, for example, depending on a number of channels desired for IC structure 800 (e.g., a GAA transistor) and/or design requirements of IC structure 800. For example, semiconductor layer stack 805 can include two to ten semiconductor layers 810 and two to ten semiconductor layers 815. In furtherance of the depicted embodiment, semiconductor layers 810 have a thickness t1 and semiconductor layers 815 have a thickness t2, where thickness t1 and thickness t2 are chosen based on fabrication and/or device performance considerations for IC structure 800. For example, thickness t1 can be configured to define a desired distance (or gap) between adjacent channels of IC structure 800 (e.g., between semiconductor layers 815), thickness t2 can be configured to achieve desired thickness of channels of IC structure 800, and both thickness t1 and thickness t2 can be configured to achieve desired performance of IC structure 800. In some embodiments, thickness t1 and thickness t2 are about 1 nm to about 10 nm.

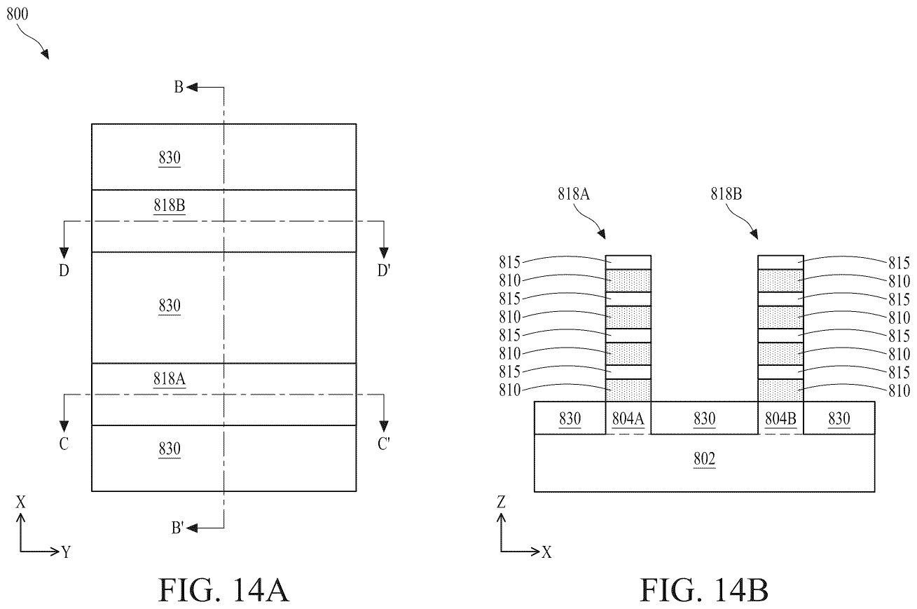

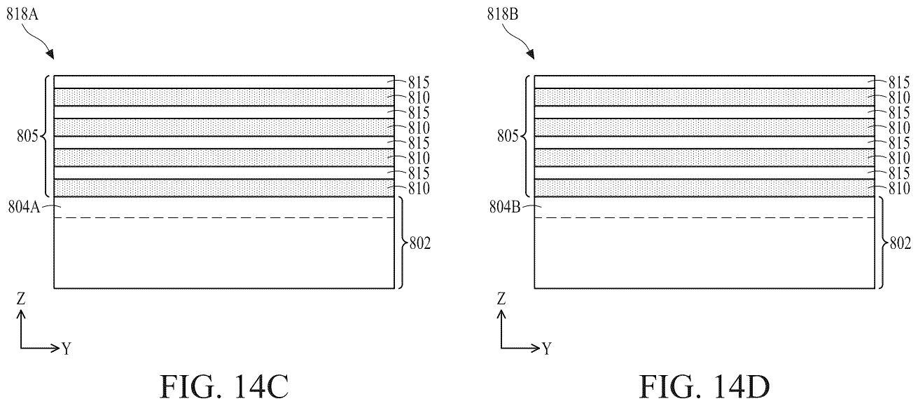

Turning to FIGS. 14A-14D, semiconductor layer stack 805 is patterned to form active regions 818A and 818B. In the disclosed embodiments, the active regions are protruded above the semiconductor substrate 802, therefore being referred to as fin structures, fin elements, or simply active regions, etc. Active regions 818A, 818B include a substrate portion (i.e., a portion of substrate 802) and a semiconductor layer stack portion (i.e., a remaining portion of semiconductor layer stack 805 including semiconductor layers 810 and semiconductor layers 815). Active regions 818A, 818B extend substantially parallel to one another along a y-direction, having a length defined in the y-direction, a width defined in an x-direction, and a height defined in a z-direction. In some implementations, a lithography and/or etching process is performed to pattern semiconductor layer stack 805 to form active regions 818A, 818B. The lithography process can include forming a resist layer over semiconductor layer stack 805 (for example, by spin coating), performing a pre-exposure baking process, performing an exposure process using a mask, performing a post-exposure baking process, and performing a developing process. During the exposure process, the resist layer is exposed to radiation energy (such as ultraviolet (UV) light, deep UV (DUV) light, or extreme UV (EUV) light), where the mask blocks, transmits, and/or reflects radiation to the resist layer depending on a mask pattern of the mask and/or mask type (for example, binary mask, phase shift mask, or EUV mask), such that an image is projected onto the resist layer that corresponds with the mask pattern. Since the resist layer is sensitive to radiation energy, exposed portions of the resist layer chemically change, and exposed (or non-exposed) portions of the resist layer are dissolved during the developing process depending on characteristics of the resist layer and characteristics of a developing solution used in the developing process. After development, the patterned resist layer includes a resist pattern that corresponds with the mask. The etching process removes portions of semiconductor layer stack 805 using the patterned resist layer as an etch mask. In some embodiments, the patterned resist layer is formed over a hard mask layer disposed over semiconductor layer stack 805, a first etching process removes portions of the hard mask layer to form a patterned hard mask layer, and a second etching process removes portions of semiconductor layer stack 805 using the patterned hard mask layer as an etch mask. The etching process can include a dry etching process, a wet etching process, other suitable etching process, or combinations thereof. In some embodiments, the etching process is a reactive ion etching (RIE) process. After the etching process, the patterned resist layer (and, in some embodiments, a hard mask layer) is removed, for example, by a resist stripping process or other suitable process. Alternatively, active regions 818A, 818B are formed by a multiple patterning process, such as a double patterning lithography (DPL) process (for example, a lithography-etch-lithography-etch (LELE) process, a self-aligned double patterning (SADP) process, a spacer-is-dielectric (SID) SADP process, other double patterning process, or combinations thereof), a triple patterning process (for example, a lithography-etch-lithography-etch-lithography-etch (LELELE) process, a self-aligned triple patterning (SATP) process, other triple patterning process, or combinations thereof), other multiple patterning process (for example, self-aligned quadruple patterning (SAQP) process), or combinations thereof. In some embodiments, directed self-assembly (DSA) techniques are implemented while patterning semiconductor layer stack 805. Further, in some embodiments, the exposure process can implement maskless lithography, electron-beam (e-beam) writing, and/or ion-beam writing for patterning the resist layer.

An isolation feature(s) 830 is formed over and/or in substrate 802 to isolate various regions, such as various device regions, of IC structure 800. For example, isolation features 830 surround a bottom portion of active regions 818A, 818B, such that isolation features 830 separate and isolate active regions 818A, 818B from each other. In the depicted embodiment, isolation features 830 surround the substrate portion of active regions 818A, 818B (e.g., doped regions 804A, 804B of substrate 802) and partially surround the semiconductor layer stack portion of active regions 818A, 818B (e.g., a portion of bottommost semiconductor layer 810). However, the present disclosure contemplates different configurations of isolation features 830 relative to active regions 818A, 818B. Isolation features 830 include silicon oxide, silicon nitride, silicon oxynitride, other suitable isolation material (for example, including silicon, oxygen, nitrogen, carbon, or other suitable isolation constituent), or combinations thereof. Isolation features 830 can include different structures, such as shallow trench isolation (STI) structures, deep trench isolation (DTI) structures, and/or local oxidation of silicon (LOCOS) structures. For example, isolation features 830 can include STI features that define and electrically isolate active regions 818A, 818B from other active device regions (such as active regions) and/or passive device regions. STI features can be formed by etching a trench in substrate 802 (for example, by using a dry etching process and/or a wet etching process) and filling the trench with insulator material (for example, by using a CVD process or a spin-on glass process). A chemical mechanical polishing (CMP) process may be performed to remove excessive insulator material and/or planarize a top surface of isolation features 830. In another example, STI features can be formed by depositing an insulator material over substrate 802 after forming active regions 818A, 818B (in some implementations, such that the insulator material layer fills gaps (trenches) between active regions 818A, 818B) and etching back the insulator material layer to form isolation features 830. In some embodiments, STI features include a multi-layer structure that fills the trenches, such as a silicon nitride comprising layer disposed over a thermal oxide comprising liner layer. In another example, STI features include a di electric layer disposed over a doped liner layer (including, for example, boron silicate glass (BSG) or phosphosilicate glass (PSG)). In yet another example, STI features include a bulk dielectric layer disposed over a liner dielectric layer, where the bulk dielectric layer and the liner dielectric layer include materials depending on design requirements.

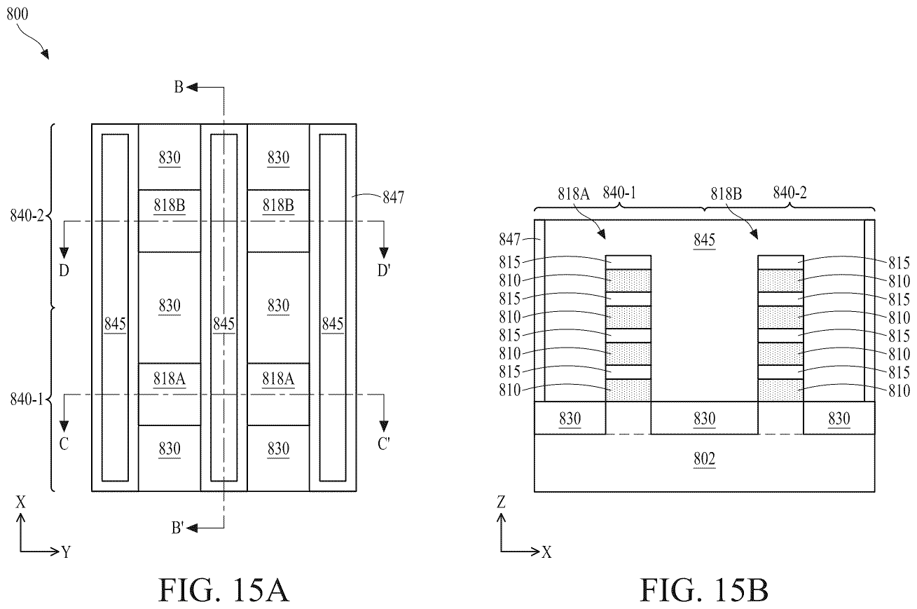

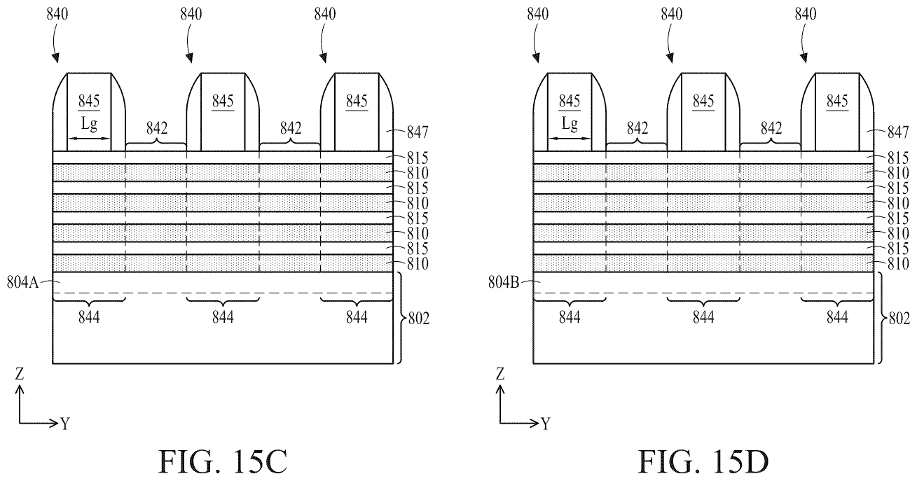

Turning to FIGS. 15A-15D, gate structures 840 are formed over portions of active regions 818A, 818B and over isolation features 830. Gate structures 840 extend lengthwise in a direction that is different than (e.g., orthogonal to) the lengthwise direction of active regions 818A, 818B. For example, gate structures 840 extend substantially parallel to one another along the x-direction, having a length defined in the y-direction, a width defined in the x-direction, and a height defined in the z-direction. Gate structures 840 are disposed on portions of active regions 818A, 818B and define source/drain regions 842 and channel regions 844 of active regions 818A, 818B. In the X-Z plane, gate structures 840 wrap top surfaces and sidewall surfaces of active regions 818A, 818B. In the Y-Z plane, gate structures 840 are disposed over top surfaces of respective channel regions 844 of active regions 818A, 818B, such that gate structures 840 interpose respective source/drain regions 842. Each gate structure 840 includes a gate region 840-1 that corresponds with a portion of the respective gate structure 840 that will be configured for an n-type GA A transistor (and thus corresponds with a portion spanning an n-type GA A transistor region) and a gate region 840-2 that corresponds with a portion of the respective gate structure 840 that will be configured for a p-type GAA transistor (and thus corresponds with a portion spanning a p-type GAA transistor region). Gate structures 840 are configured differently in gate region 840-1 and gate region 840-2. For example, as described further below, each metal gate stack of gate structures 840 spans gate region 840-1 and gate region 840-2 and is configured differently in gate region 840-1 and gate region 840-2 to optimize performance of the n-type GAA transistors (having n-gate electrodes in gate regions 840-1) and the p-type GAA transistors (having p-gate electrodes in gate regions 840-2). Accordingly, gate regions 840-1 will be referred to as n-type gate regions 840-1 and gate regions 840-2 will be referred to as p-type gate regions 840-2 hereinafter.

In FIGS. 15A-15D, each gate structure 840 includes a dummy gate stack 845. In the depicted embodiment, a width of dummy gate stacks 845 defines a gate length (Lg) of gate structures 840 (here, in the y-direction), where the gate length defines a distance (or length) that current (e.g., carriers, such as electrons or holes) travels between source/drain regions 842 when the n-type GA A transistor and/or the p-type GA A transistor are switched (turned) on. In some embodiments, the gate length is about 5 nm to about 850 nm. Gate length can be tuned to achieve desired operation speeds of the GA A transistors and/or desired packing density of the GAA transistors. For example, when a GAA transistor is switched on, current flows between source/drain regions of the GAA transistor. Increasing the gate length increases a distance required for current to travel between the source/drain regions, increasing a time it takes for the GAA transistor to switch fully on. Conversely, decreasing the gate length decreases the distance required for current to travel between the source/drain regions, decreasing a time it takes for the GAA transistor to switch fully on. Smaller gate lengths provide GAA transistors that switch on/off more quickly, facilitating faster, high speed operations. Smaller gate lengths also facilitate tighter packing density (i.e., more GA A transistors can be fabricated in a given area of an IC chip), increasing a number of functions and applications that can be fabricated on the IC chip. In the depicted embodiment, the gate length of one or more of gate structures 840 is configured to provide GAA transistors having short-length (SC) channels. For example, the gate length of SC GAA transistors is about 5 nm to about 20 nm. In some embodiments, IC structure 800 can include GAA transistors having different gate lengths. For example, a gate length of one or more of gate structures 840 can be configured to provide GA A transistors having mid-length or long-length channels (M/LC). In some embodiments, the gate length of M/LC GAA transistors is about 20 nm to about 850 nm.

Dummy gate stacks 845 include a dummy gate electrode, and in some embodiments, a dummy gate dielectric. The dummy gate electrode includes a suitable dummy gate material, such as polysilicon layer. In embodiments where dummy gate stacks 845 include a dummy gate dielectric disposed between the dummy gate electrode and active regions 818A, 818B, the dummy gate dielectric includes a dielectric material, such as silicon oxide, a high-k dielectric material, other suitable dielectric material, or combinations thereof. Examples of high-k dielectric material include HfO₂, HfSiO, HfSiON, HfTaO, HfTiO, HfZrO, zirconium oxide, aluminum oxide, hafnium dioxide-alumina (HfO₂—Al₂O₃) alloy, other suitable high-k dielectric materials, or combinations thereof. In some embodiments, the dummy gate dielectric includes an interfacial layer (including, for example, silicon oxide) disposed over active regions 818A, 818B and a high-k dielectric layer disposed over the interfacial layer. Dummy gate stacks 845 can include numerous other layers, for example, capping layers, interface layers, diffusion layers, barrier layers, hard mask layers, or combinations thereof. For example, dummy gate stacks 845 can further include a hard mask layer disposed over the dummy gate electrode.

Dummy gate stacks 845 are formed by deposition processes, lithography processes, etching processes, other suitable processes, or combinations thereof. For example, a deposition process is performed to form a dummy gate electrode layer over active regions 818A, 818B and isolation features 830. In some embodiments, a deposition process is performed to form a dummy gate dielectric layer over active regions 818A, 818B and isolation features 830 before forming the dummy gate electrode layer. In such embodiments, the dummy gate electrode layer is deposited over the dummy gate dielectric layer. In some embodiment, a hard mask layer is deposited over the dummy gate electrode layer. The deposition process includes CVD, physical vapor deposition (PV D), atomic layer deposition (ALD), high density plasma CVD (HDPCVD), metal organic CVD (MOCVD), remote plasma CVD (RPCVD), plasma enhanced CVD (PECVD), low-pressure CVD (LPCVD), atomic layer CVD (ALCVD), atmospheric pressure CVD (APCVD), plating, other suitable methods, or combinations thereof. A lithography patterning and etching process is then performed to pattern the dummy gate electrode layer (and, in some embodiments, the dummy gate dielectric layer and the hard mask layer) to form dummy gate stacks 845, such that dummy gate stacks 845 (including the dummy gate electrode layer, the dummy gate dielectric layer, the hard mask layer, and/or other suitable layers) is configured as depicted in FIGS. 15A-15D. The lithography patterning processes include resist coating (for example, spin-on coating), soft baking, mask aligning, exposure, post-exposure baking, developing the resist, rinsing, drying (for example, hard baking), other suitable lithography processes, or combinations thereof. The etching processes include dry etching processes, wet etching processes, other etching methods, or combinations thereof.

Each gate structure 840 further includes gate spacers 847 disposed adjacent to (i.e., along sidewalls of) respective dummy gate stacks 845. Gate spacers 847 are formed by any suitable process and include a dielectric material. The dielectric material can include silicon, oxygen, carbon, nitrogen, other suitable material, or combinations thereof (e.g., silicon oxide, silicon nitride, silicon oxynitride (SiON), silicon carbide, silicon carbon nitride (SiCN), silicon oxycarbide (SiOC), silicon oxycarbon nitride (SiOCN)). For example, a dielectric layer including silicon and nitrogen, such as a silicon nitride layer, can be deposited over dummy gate stacks 845 and subsequently etched (e.g., anisotropically etched) to form gate spacers 847. In some embodiments, gate spacers 847 include a multi-layer structure, such as a first dielectric layer that includes silicon nitride and a second dielectric layer that includes silicon oxide. In some embodiments, more than one set of spacers, such as seal spacers, offset spacers, sacrificial spacers, dummy spacers, and/or main spacers, are formed adjacent to dummy gate stacks 845. In such implementations, the various sets of spacers can include materials having different etch rates. For example, a first dielectric layer including silicon and oxygen (e.g., silicon oxide) can be deposited and etched to form a first spacer set adjacent to dummy gate stacks 845, and a second dielectric layer including silicon and nitrogen (e.g., silicon nitride) can be deposited and etched to form a second spacer set adjacent to the first spacer set.

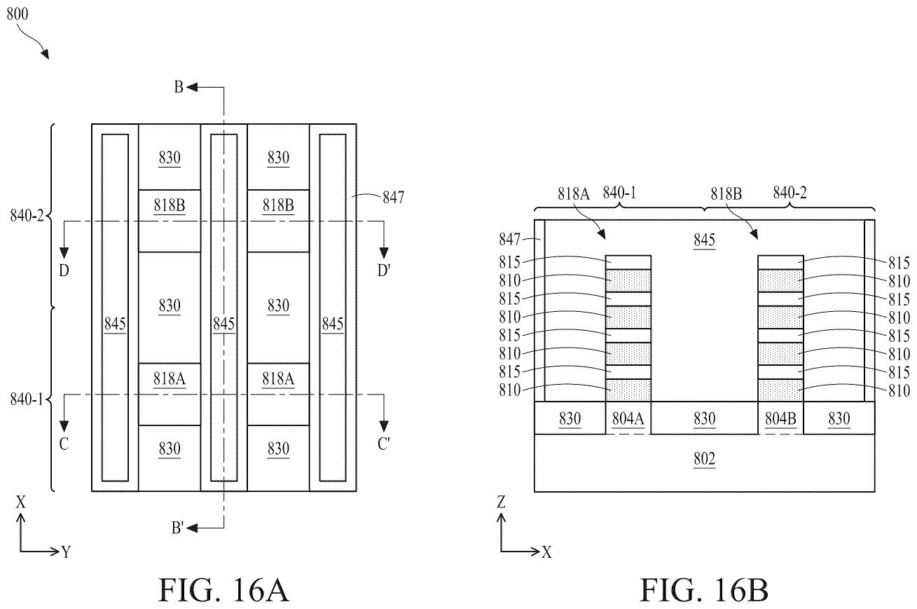

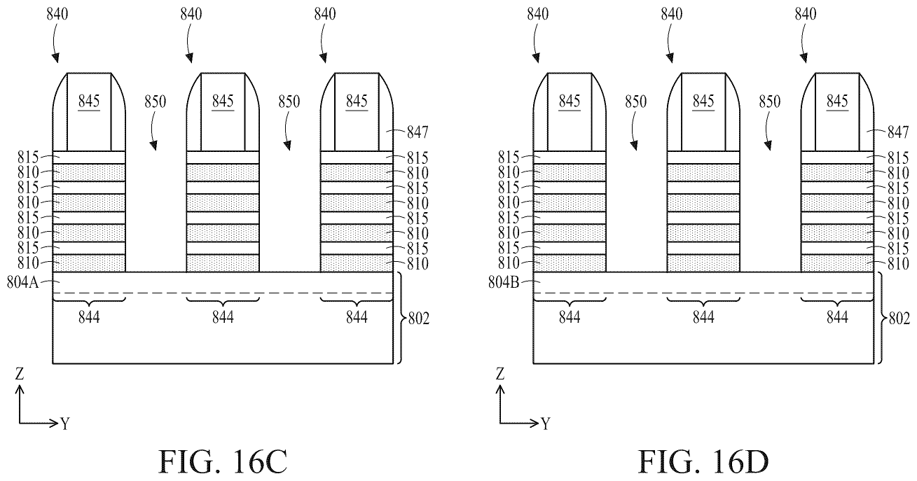

Turning to FIGS. 16A-16D, exposed portions of active regions 818A, 818B (i.e., source/drain regions 842 of active regions 818A, 818B that are not covered by gate structures 840) are at least partially removed to form source/drain trenches (recesses) 850. In the depicted embodiment, an etching process completely removes semiconductor layer stack 805 in source/drain regions 842 of active regions 818A, 818B, thereby exposing the substrate portion of active regions 818A, 818B in source/drain regions 842 (e.g., p-well 804A and n-well 804B). Source/drain trenches 850 thus have sidewalls defined by remaining portions of semiconductor layer stack 805, which are disposed in channel regions 844 under gate structures 840, and bottoms defined by substrate 802, such as top surfaces of p-well 804A and n-well 804B in source/drain regions 842. In some embodiments, the etching process removes some, but not all, of semiconductor layer stack 805, such that source/drain trenches 850 have bottoms defined by semiconductor layer 810 or semiconductor layer 815 in source/drain regions 842. In some embodiments, the etching process further removes some, but not all, of the substrate portion of active regions 818A, 818B, such that source/drain recesses 850 extend below a topmost surface of substrate 802. The etching process can include a dry etching process, a wet etching process, other suitable etching process, or combinations thereof. In some embodiments, the etching process is a multi-step etch process. For example, the etching process may alternate etchants to separately and alternately remove semiconductor layers 810 and semiconductor layers 815. In some embodiments, parameters of the etching process are configured to selectively etch semiconductor layer stack with minimal (to no) etching of gate structures 840 (i.e., dummy gate stacks 845 and gate spacers 847) and/or isolation features 830. In some embodiments, a lithography process, such as those described herein, is performed to form a patterned mask layer that covers gate structures 840 and/or isolation features 830, and the etching process uses the patterned mask layer as an etch mask.

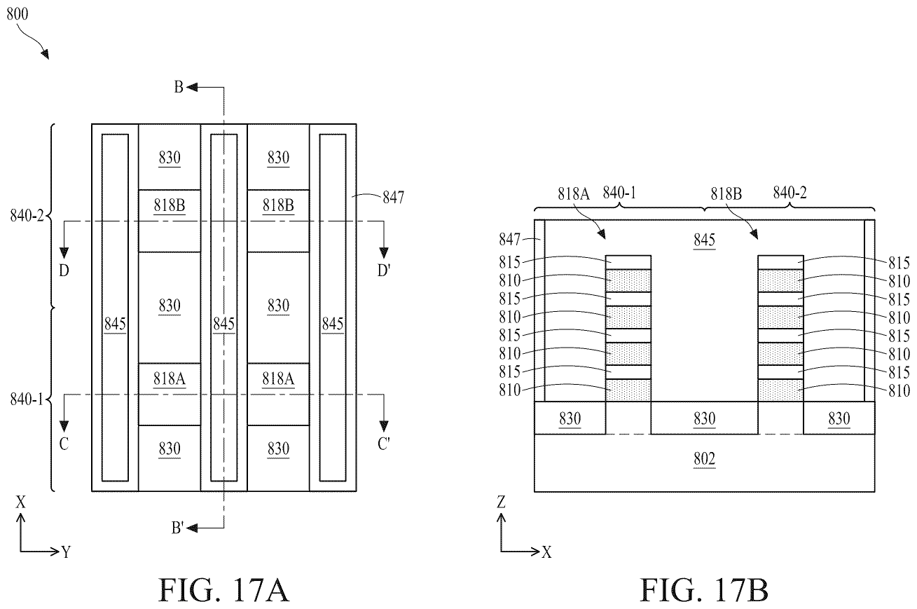

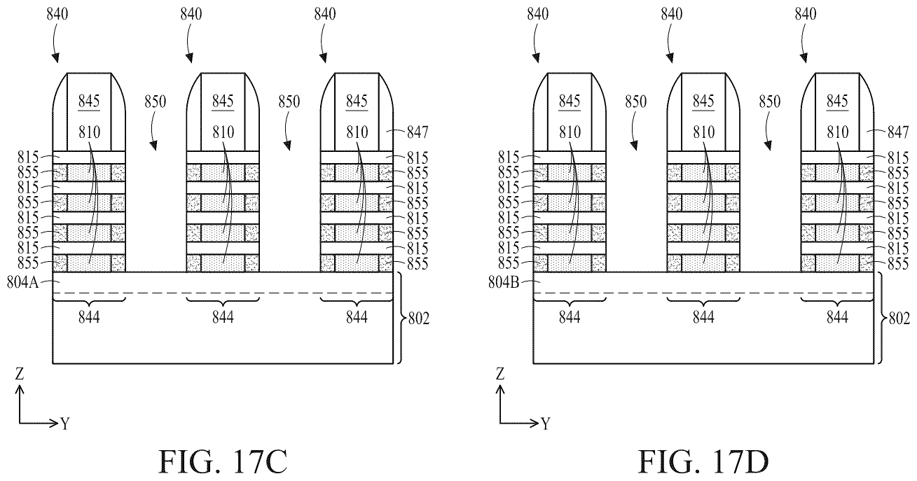

Turning to FIGS. 17A-17D, inner spacers 855 are formed in channel regions 844 along sidewalls of semiconductor layers 810 by any suitable process. For example, a first etching process is performed that selectively etches semiconductor layers 810 exposed by source/drain trenches 850 with minimal (to no) etching of semiconductor layers 815, such that gaps are formed between semiconductor layers 815 and between semiconductor layers 815 and substrate 802 under gate spacers 847. Portions (edges) of semiconductor layers 815 are thus suspended in the channel regions 844 under gate spacers 847. In some embodiments, the gaps extend partially under dummy gate stacks 845. The first etching process is configured to laterally etch (e.g., along the y-direction) semiconductor layers 810, thereby reducing a length of semiconductor layers 810 along the y-direction. The first etching process is a dry etching process, a wet etching process, other suitable etching process, or combinations thereof. A deposition process then forms a spacer layer over gate structures 840 and over features defining source/drain trenches 850 (e.g., semiconductor layers 815, semiconductor layers 810, and substrate 802), such as CVD, PVD, ALD, HDPCVD, MOCVD, RPCVD, PECVD, LPCVD, ALCVD, APCVD, plating, other suitable methods, or combinations thereof. The spacer layer partially (and, in some embodiments, completely) fills the source/drain trenches 850. The deposition process is configured to ensure that the spacer layer fills the gaps between semiconductor layers 815 and between semiconductor layers 815 and substrate 802 under gate spacers 847. A second etching process is then performed that selectively etches the spacer layer to form inner spacers 855 as depicted in FIGS. 6A-6D with minimal (to no) etching of semiconductor layers 815, dummy gate stacks 845, and gate spacers 847. In some embodiments, the spacer layer is removed from sidewalls of gate spacers 847, sidewalls of semiconductor layers 815, dummy gate stacks 845, and substrate 802. The spacer layer (and thus inner spacers 855) includes a material that is different than a material of semiconductor layers 815 and a material of gate spacers 847 to achieve desired etching selectivity during the second etching process. In some embodiments, the spacer layer includes a dielectric material that includes silicon, oxygen, carbon, nitrogen, other suitable material, or combinations thereof (for example, silicon oxide, silicon nitride, silicon oxynitride, silicon carbide, or silicon oxycarbonitride). In some embodiments, the spacer layer includes a low-k dielectric material, such as those described herein. In some embodiments, dopants (for example, p-type dopants, n-type dopants, or combinations thereof) are introduced into the dielectric material, such that spacer layer includes a doped dielectric material.

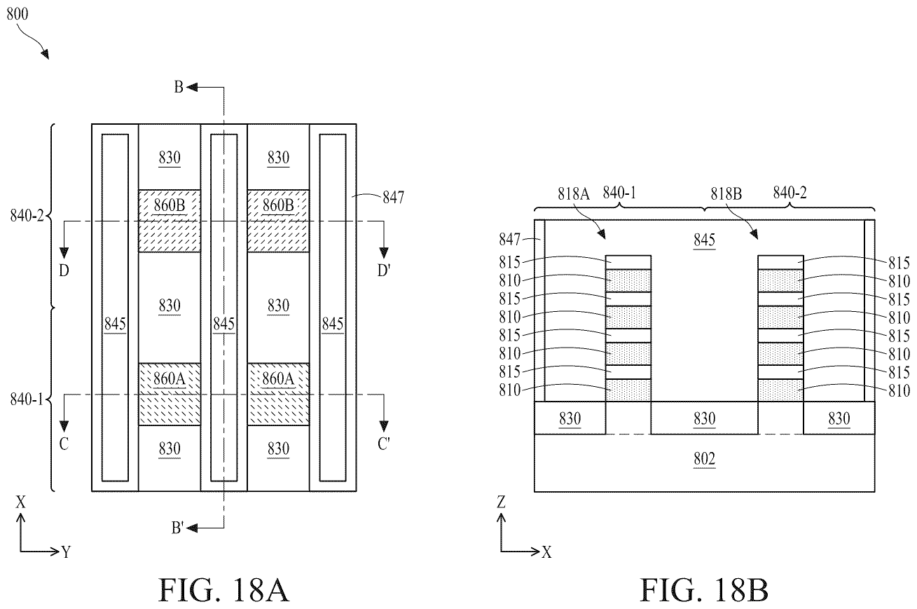

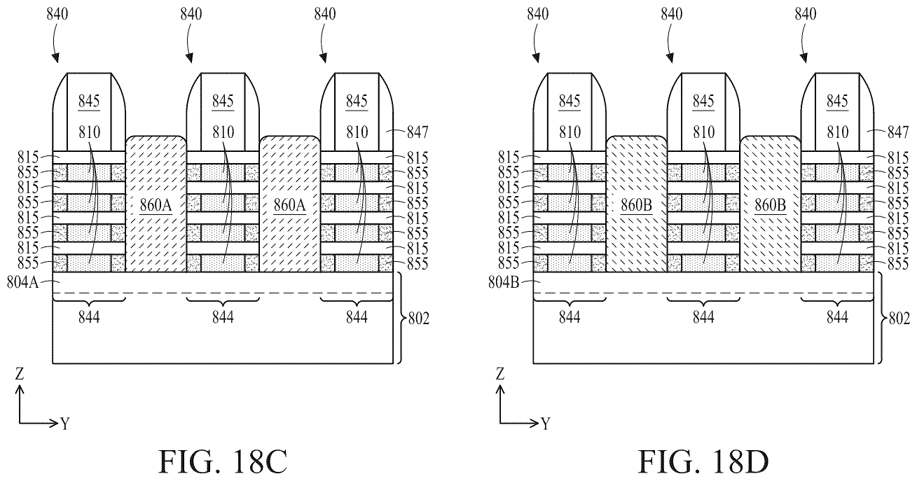

Turning to FIGS. 18A-18D, epitaxial source/drain features are formed in source/drain recesses 850. For example, a semiconductor material is epitaxially grown from portions of substrate 802 and semiconductor layers 815 exposed by source/drain recesses 850, forming epitaxial source/drain features 860A in source/drain regions 842 that correspond with n-type GAA transistor regions and epitaxial source/drain features 860B in source/drain regions 842 that correspond with p-type GAA transistor regions. An epitaxy process can use CVD deposition techniques (for example, VPE and/or UHV-CVD), molecular beam epitaxy, other suitable epitaxial growth processes, or combinations thereof. The epitaxy process can use gaseous and/or liquid precursors, which interact with the composition of substrate 802 and/or semiconductor layer stack 805 (in particular, semiconductor layers 815). Epitaxial source/drain features 860A, 860B are doped with n-type dopants and/or p-type dopants. In some embodiments, for the n-type GAA transistors, epitaxial source/drain features 860A include silicon. Epitaxial source/drain features 860A can be doped with carbon, phosphorous, arsenic, other n-type dopant, or combinations thereof (for example, forming Si:C epitaxial source/drain features, Si:P epitaxial source/drain features, or Si:C:P epitaxial source/drain features). In some embodiments, for the p-type GAA transistors, epitaxial source/drain features 860B include silicon germanium or germanium. Epitaxial source/drain features 860B can be doped with boron, other p-type dopant, or combinations thereof (for example, forming Si:Ge:B epitaxial source/drain features). In some embodiments, epitaxial source/drain features 860A and/or epitaxial source/drain features 860B include more than one epitaxial semiconductor layer, where the epitaxial semiconductor layers can include the same or different materials and/or dopant concentrations. In some embodiments, epitaxial source/drain features 860A, 860B include materials and/or dopants that achieve desired tensile stress and/or compressive stress in respective channel regions 844. In some embodiments, epitaxial source/drain features 860A, 860B are doped during deposition by adding impurities to a source material of the epitaxy process (i.e., in-situ). In some embodiments, epitaxial source/drain features 860A, 860B are doped by an ion implantation process subsequent to a deposition process. In some embodiments, annealing processes (e.g., rapid thermal annealing (RTA) and/or laser annealing) are performed to activate dopants in epitaxial source/drain features 860A, 860B and/or other source/drain regions (for example, heavily doped source/drain regions and/or lightly doped source/drain (LDD) regions). In some embodiments, epitaxial source/drain features 860A, 860B are formed in separate processing sequences that include, for example, masking p-type GAA transistor regions when forming epitaxial source/drain features 860A in n-type GAA transistor regions and masking n-type GAA transistor regions when forming epitaxial source/drain features 860B in p-type GAA transistor regions.

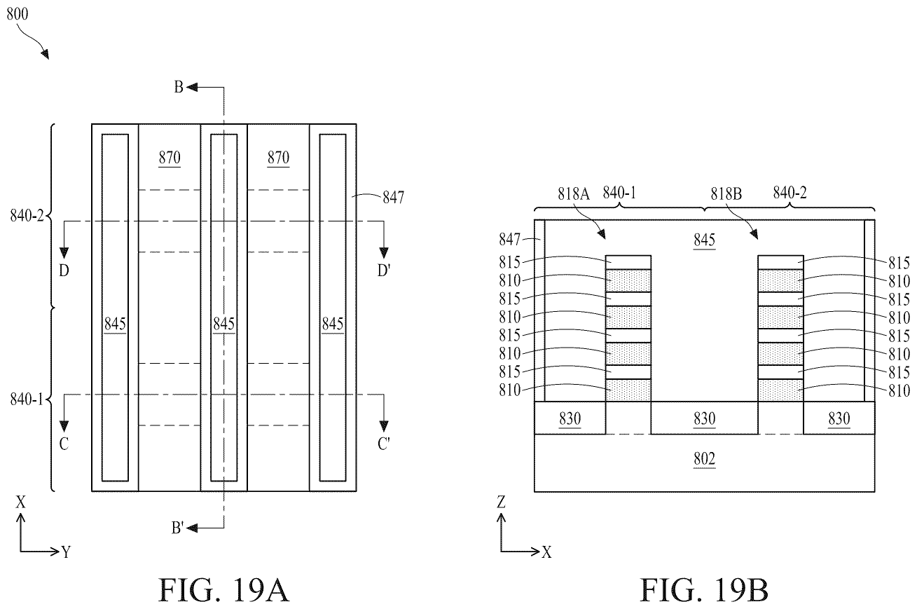

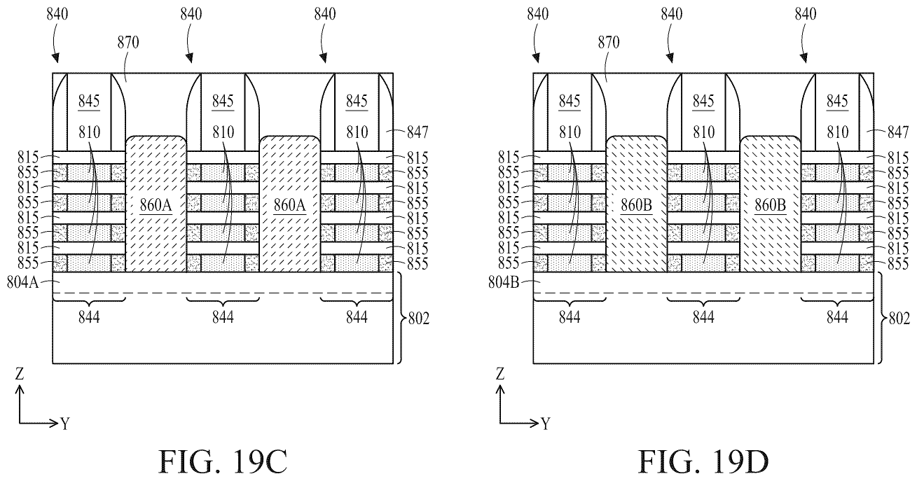

Turning to FIGS. 19A-19D, an inter-level dielectric (IL D) layer 870 is formed over isolation features 830, epitaxial source/drain features 860A, 860B, and gate spacers 847, for example, by a deposition process (such as CVD, PVD, ALD, HDPCVD, MOCVD, RPCVD, PECVD, LPCVD, ALCVD, APCVD, plating, other suitable methods, or combinations thereof). ILD layer 870 is disposed between adjacent gate structures 840. In some embodiments, IL D layer 870 is formed by a flowable CVD (FCVD) process that includes, for example, depositing a flowable material (such as a liquid compound) over IC structure 800 and converting the flowable material to a solid material by a suitable technique, such as thermal annealing and/or ultraviolet radiation treating. ILD layer 870 includes a dielectric material including, for example, silicon oxide, silicon nitride, silicon oxynitride, TEOS formed oxide, PSG, BPSG, low-k dielectric material, other suitable dielectric material, or combinations thereof. Exemplary low-k dielectric materials include FSG, carbon doped silicon oxide, Black Diamond® (Applied Materials of Santa Clara, California), Xerogel, Aerogel, amorphous fluorinated carbon, Parylene, BCB, SILK (Dow Chemical, Midland, Michigan), polyimide, other low-k dielectric material, or combinations thereof. In the depicted embodiment, ILD layer 870 is a dielectric layer that includes a low-k dielectric material (generally referred to as a low-k dielectric layer). IL D layer 870 can include a multilayer structure having multiple dielectric materials. In some embodiments, a contact etch stop layer (CESL) is disposed between ILD layer 870 and isolation features 830, epitaxial source/drain features 860A, 860B, and gate spacers 847. The CESL includes a material different than ILD layer 870, such as a dielectric material that is different than the dielectric material of ILD layer 870. For example, where ILD layer 870 includes a low-k dielectric material, the CESL includes silicon and nitrogen, such as silicon nitride or silicon oxynitride. Subsequent to the deposition of ILD layer 870 and/or the CESL, a CMP process and/or other planarization process can be performed until reaching (exposing) a top portion (or top surface) of dummy gate stacks 845. In some embodiments, the planarization process removes hard mask layers of dummy gate stacks 845 to expose underlying dummy gate electrodes of dummy gate stacks 845, such as polysilicon gate electrode layers.

ILD layer 870 may be a portion of a multilayer interconnect (MLI) feature disposed over substrate 802. The MLI feature electrically couples various devices (for example, p-type GAA transistors and/or n-type GAA transistors of IC structure 800, transistors, resistors, capacitors, and/or inductors) and/or components (for example, gate structures and/or epitaxial source/drain features of p-type GAA transistors and/or n-type GA A transistors), such that the various devices and/or components can operate as specified by design requirements of IC structure 800. The MLI feature includes a combination of dielectric layers and electrically conductive layers (e.g., metal layers) configured to form various interconnect structures. The conductive layers are configured to form vertical interconnect features, such as device-level contacts and/or vias, and/or horizontal interconnect features, such as conductive lines. Vertical interconnect features typically connect horizontal interconnect features in different layers (or different planes) of the MLI feature. During operation, the interconnect features are configured to route signals between the devices and/or the components of IC structure 800 and/or distribute signals (for example, clock signals, voltage signals, and/or ground signals) to the devices and/or the components of IC structure 800.

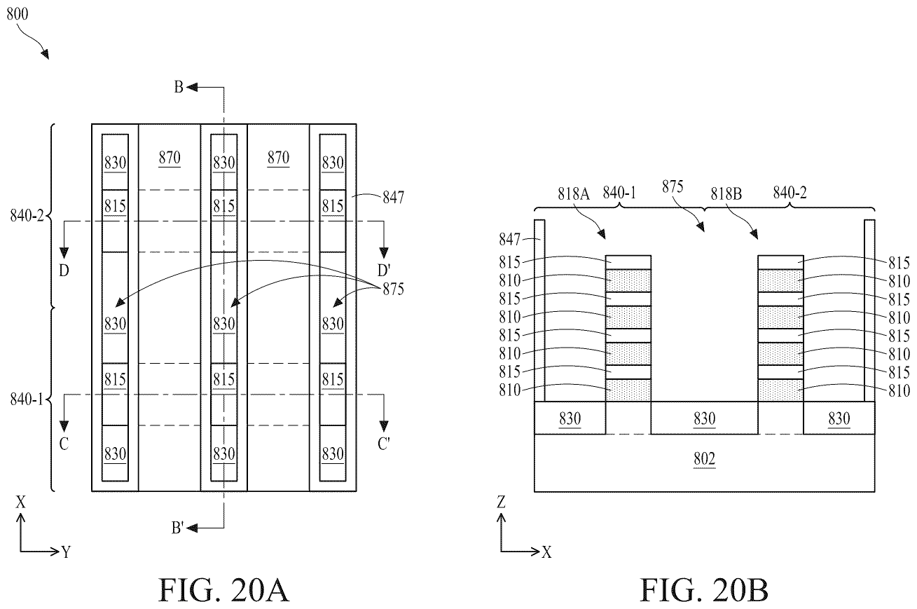

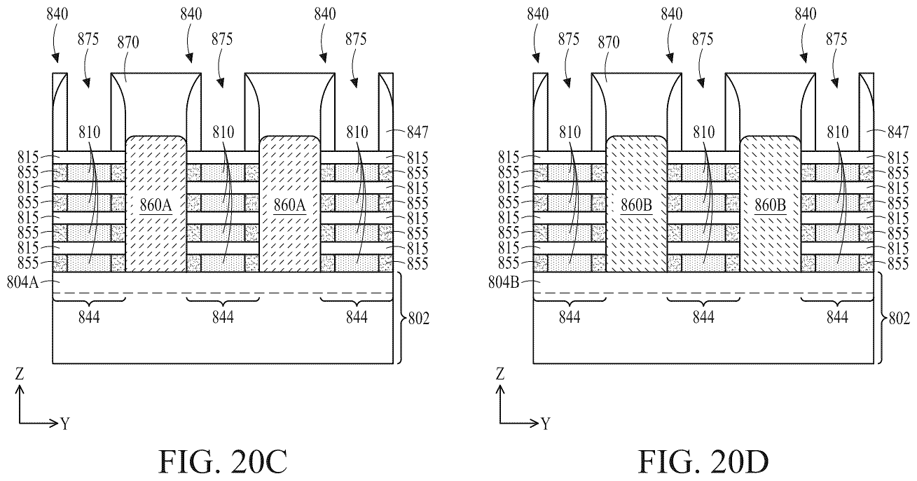

Turning to FIGS. 20A-20D, dummy gate stacks 845 are removed from gate structures 840, thereby forming gate trenches 875 and exposing semiconductor layer stacks 805 of active regions 818A, 818B in n-type gate regions 840-1 and p-type gate regions 840-2. In the depicted embodiment, an etching process completely removes dummy gate stacks 845 to expose semiconductor layers 815 and semiconductor layers 810 in channel regions 844. The etching process is a dry etching process, a wet etching process, other suitable etching process, or combinations thereof. In some embodiments, the etching process is a multi-step etch process. For example, the etching process may alternate etchants to separately remove various layers of dummy gate stacks 845, such as the dummy gate electrode layers, the dummy gate dielectric layers, and/or the hard mask layers. In some embodiments, the etching process is configured to selectively etch dummy gate stacks 845 with minimal (to no) etching of other features of IC structure 800, such as ILD layer 870, gate spacers 847, isolation features 830, semiconductor layers 815, and semiconductor layers 810. In some embodiments, a lithography process, such as those described herein, is performed to form a patterned mask layer that covers ILD layer 870 and/or gate spacers 847, and the etching process uses the patterned mask layer as an etch mask.

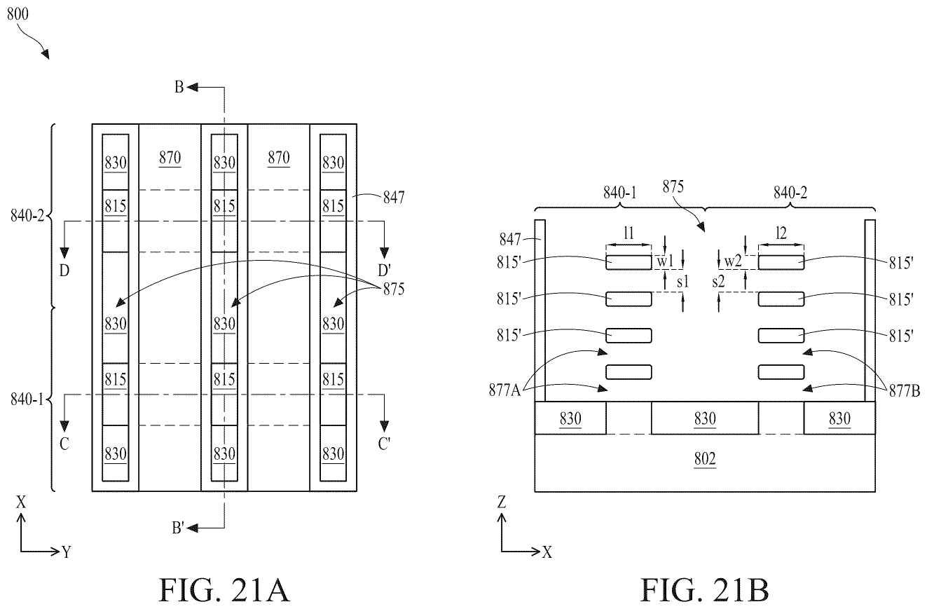

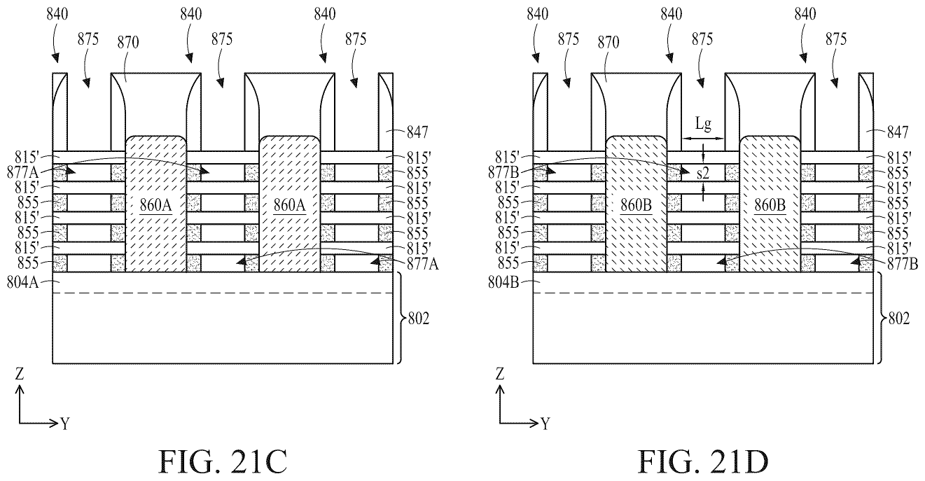

Turning to FIGS. 21A-21D, semiconductor layers 810 of semiconductor layer stack 805 (exposed by gate trenches 875) are selectively removed from channel regions 844, thereby forming suspended semiconductor layers 815′ in channel regions 844. In the depicted embodiment, an etching process selectively etches semiconductor layers 810 with minimal (to no) etching of semiconductor layers 815 and, in some embodiments, minimal (to no) etching of gate spacers 847 and/or inner spacers 855. Various etching parameters can be tuned to achieve selective etching of semiconductor layers 810, such as etchant composition, etching temperature, etching solution concentration, etching time, etching pressure, source power, RF bias voltage, RF bias power, etchant flow rate, other suitable etching parameters, or combinations thereof. For example, an etchant is selected for the etching process that etches the material of semiconductor layers 810 (in the depicted embodiment, silicon germanium) at a higher rate than the material of semiconductor layers 815 (in the depicted embodiment, silicon) (i.e., the etchant has a high etch selectivity with respect to the material of semiconductor layers 810). The etching process is a dry etching process, a wet etching process, other suitable etching process, or combinations thereof. In some embodiments, a dry etching process (such as an RIE process) utilizes a fluorine-containing gas (for example, SF₆) to selectively etch semiconductor layers 810. In some embodiments, a ratio of the fluorine-containing gas to an oxygen-containing gas (for example, O₂), an etching temperature, and/or an RF power may be tuned to selectively etch silicon germanium or silicon. In some embodiments, a wet etching process utilizes an etching solution that includes ammonium hydroxide (NH₄OH) and water (H₂O) to selectively etch semiconductor layers 810. In some embodiments, a chemical vapor phase etching process using hydrochloric acid (HCl) selectively etches semiconductor layers 810.

At least one suspended semiconductor layer 815′ is thus exposed in n-type gate regions 840-1 and p-type gate regions 840-2 by gate trenches 875. In the depicted embodiment, each n-type gate region 840-1 and each p-type gate region 840-2 includes four suspended semiconductor layers 815′ vertically stacked that will provide four channels through which current will flow between respective epitaxial source/drain features (epitaxial source/drain features 860A or epitaxial source/drain features 860B) during operation of the GAA transistors. Suspended semiconductor layers 815′ are thus referred to as channel layers 815′ hereinafter. Channel layers 815′ in n-type gate regions 840-1 are separated by gaps 877A, and channel layers 815′ in p-type gate regions 840-2 are separated by gaps 877B. Channel layers 815′ in n-type gate regions 840-1 are also separated from substrate 802 by gaps 877A, and channel layers 815′ in p-type gate regions 840-2 are also separated by gaps 877B. A spacing s1 is defined between channel layers 815′ along the z-direction in n-type gate regions 840-1, and a spacing s2 is defined between channel layers 815′ along the z-direction in p-type gate regions 840-2. Spacing s1 and spacing s2 correspond with a width of gaps 877A and gaps 877B, respectively. In the depicted embodiment, spacing s1 is about equal to s2, though the present disclosure contemplates embodiments where spacing s1 is different than spacing s2. In some embodiments, spacing s1 and spacing s2 are both about equal to thickness t1 of semiconductor layers 810. Further, channel layers 815′ in n-type gate regions 840-1 have a length l1 along the x-direction and a width w1 along the y-direction, and channel layers 815′ in p-type gate regions 840-2 have a length l2 along the y-direction and a width w2 along the x-direction. In the depicted embodiment, length l1 is about equal to length l2, and width w1 is about equal to width w2, though the present disclosure contemplates embodiments where length l1 is different than length l2 and/or width w1 is different than width w2. In some embodiments, length l1 and/or length l2 is about 10 nm to about 50 nm. In some embodiments, width w1 and/or width w2 is about 4 nm to about 10 nm. In some embodiments, each channel layer 815′ has nanometer-sized dimensions and can be referred to as a “nanowire,” which generally refers to a channel layer suspended in a manner that will allow a metal gate to physically contact at least two sides of the channel layer, and in GAA transistors, will allow the metal gate to physically contact at least four sides of the channel layer (i.e., surround the channel layer). In such embodiments, a vertical stack of suspended channel layers can be referred to as a nanostructure, and the process depicted in FIGS. 10A-10D can be referred to as a channel nanowire release process. In some embodiments, after removing semiconductor layers 810, an etching process is performed to modify a profile of channel layers 815′ to achieve desired dimensions and/or desired shapes (e.g., cylindrical-shaped (e.g., nanowire), rectangular-shaped (e.g., nanobar), sheet-shaped (e.g., nanosheet), etc.). The present disclosure further contemplates embodiments where the channel layers 815′ (nanowires) have sub-nanometer dimensions depending on design requirements of IC structure 800.

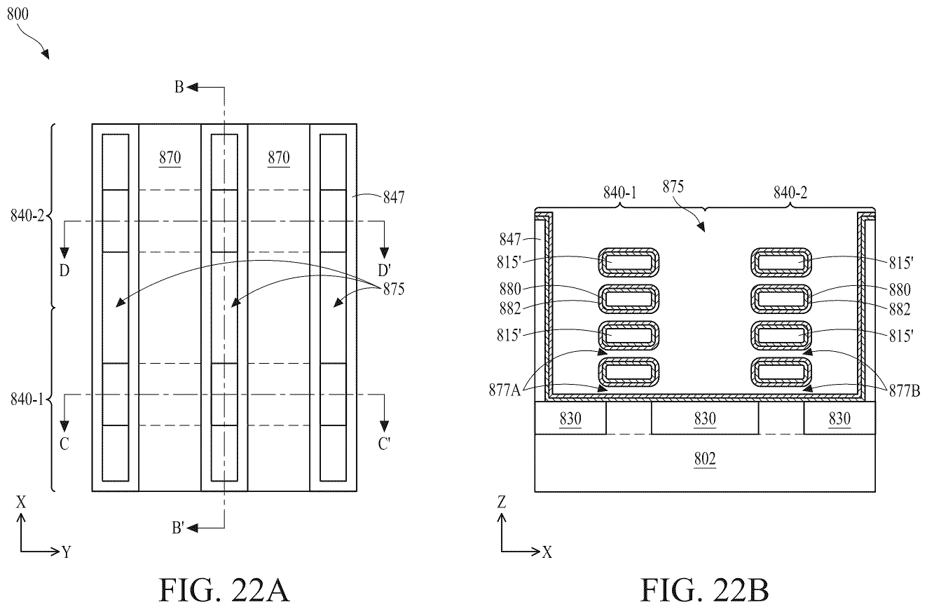

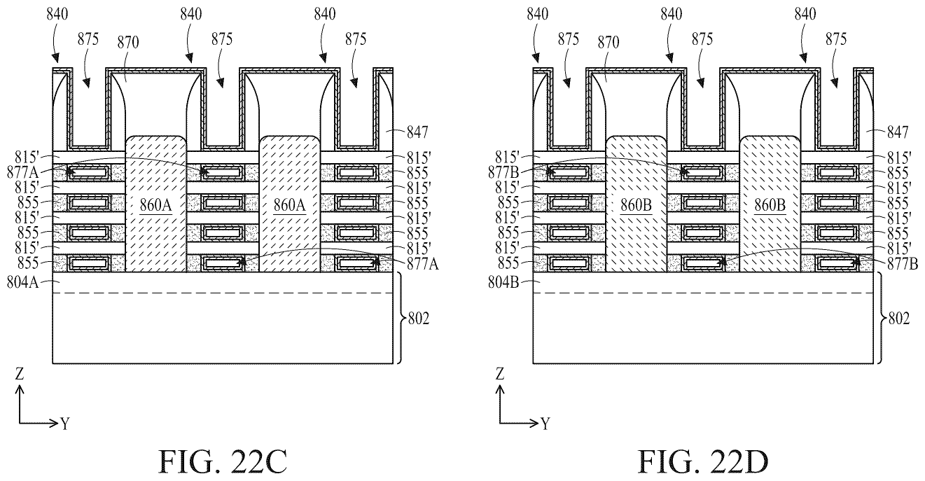

Turning to FIGS. 22A-22D, a gate dielectric layer is formed over IC structure 800, where the gate dielectric layer partially fills gate trenches 875 and wraps (surrounds) channel layers 815′ in n-type gate regions 840-1 and p-type gate regions 840-2 of gate structures 840. In the depicted embodiment, the gate dielectric layer includes an interfacial layer 880 and a high-k dielectric layer 882, where interfacial layer 880 is disposed between the high-k dielectric layer 882 and channel layers 815′. In furtherance of the depicted embodiment, interfacial layer 880 and high-k dielectric layer 882 partially fill gaps 877A between channel layers 815′ and between channel layers 815′ and substrate 802 in n-type gate regions 840-1 and partially fill gaps 877B between channel layers 815′ and between channel layers 815′ and substrate 802 in p-type gate regions 840-2. In some embodiments, interfacial layer 880 and/or high-k dielectric layer 882 are also disposed on substrate 802, isolation features 830, and/or gate spacers 847. Interfacial layer 880 includes a dielectric material, such as SiO₂, HfSiO, SiON, other silicon-comprising dielectric material, other suitable dielectric material, or combinations thereof. High-k dielectric layer 882 includes a high-k dielectric material, such as HfO₂, HfSiO, HfSiO₄, HfSiON, HfLaO, HfTaO, HfTiO, HfZrO, HfAlOₓ, ZrO, ZrO₂, ZrSiO₂, AlO, AlSiO, Al₂O₃, TIO, TiO₂, LaO, LaSiO, Ta₂O₃, Ta₂O₅, Y₂O₃, SrTiO₃, BaZrO, BaTiO₃(BTO), (Ba,Sr)TiO₃(BST), Si₃N₄, hafnium dioxide-alumina (HfO₂—Al₂O₃) alloy, other suitable high-k dielectric material, or combinations thereof. High-k dielectric material generally refers to dielectric materials having a high dielectric constant, for example, greater than that of silicon oxide (k≈3.9). Interfacial layer 880 is formed by any of the processes described herein, such as thermal oxidation, chemical oxidation, ALD, CVD, other suitable process, or combinations thereof. In some embodiments, interfacial layer 880 has a thickness of about 0.5 nm to about 3 nm. High-k dielectric layer 882 is formed by any of the processes described herein, such as ALD, CVD, PVD, oxidation-based deposition process, other suitable process, or combinations thereof. In some embodiments, high-k dielectric layer 882 has a thickness of about 1 nm to about 2 nm.

Turning to FIGS. 23A-23D, gate electrodes 884 is deposited over IC structure 800, where gate electrodes 884 fill gate trenches 875 and wraps (surrounds) channel layers 815′ in n-type gate regions 840-1 and p-type gate regions 840-2. Gate electrodes 884 are deposited on the gate dielectric layer by any of the processes described herein, such as ALD, CVD, PVD, other suitable process, or combinations thereof. In the depicted embodiment, gate electrodes 884 are disposed on high-k dielectric layer 882 and surrounds high-k dielectric layer 882, interfacial layer 880, and channel layers 815′. For example, gate electrodes 884 are disposed along sidewalls, tops, and bottoms of channel layers 815′. A thickness of gate electrodes 884 is configured to fill any remaining portion of gaps 877A between channel layers 815′ in n-type gate regions 840-1 and any remaining portion of gaps 877B between channel layers 815′ in p-type gate regions 840-2 and gate trenches 875. In some embodiments, gate electrodes 884 include a cap layer, a work function metal layer, a glue layer, a fill metal layer, other suitable conductive layer or a combination thereof.

In some embodiments, the gate electrodes 884 in n-type gate regions 840-1 and p-type gate regions 840-2 are different in composition, therefore being referred to by the numerical 884A and 884B respectively. For example, the gate electrodes 884A include a n-type work function metal and the gate electrodes 884B include a p-type work function metal.

In the depicted embodiment, p-type work function layer includes any suitable p-type work function material, such as TlN, TaN, TaSN, Ru, Mo, Al, WN, WCN ZrSi₂, MoSi₂, TaSi₂, NiSi₂, other p-type work function material, or combinations thereof. In the depicted embodiment, p-type work function layer includes titanium and nitrogen, such as TiN. P-type work function layer 300 can be formed using another suitable deposition process, such as CVD, PVD, HDPCVD, MOCVD, RPCVD, PECVD, LPCVD, ALCVD, APCVD, spin coating, plating, other deposition process, or combinations thereof.

In the depicted embodiment, N-type work function layer includes any suitable n-type work function material, such as Ti, Al, Ag, Mn, Zr, TiAl, TiAlC, TiAlSiC, TaC, TaCN, TaSiN, TaAl, TaAlC, TaSiA IC, TiAlN, other n-type work function material, or combinations thereof. In the depicted embodiment, n-type work function layer includes aluminum. Alternatively, n-type work function layer includes titanium and aluminum, such as TiAl, TiAlC, TaSiAl, or TiSiAlC. The n-type work function layer is formed using another suitable deposition process, such as CVD, PVD, HDPCVD, MOCVD, RPCVD, PECVD, LPCVD, ALCVD, APCVD, spin coating, plating, other deposition process, or combinations thereof.

A metal fill (or bulk) layer is formed over IC structure 800, particularly over n-type work function layer in n-type gate regions 840-1 and over p-type work function layer in p-type gate regions 840-2. For example, a CVD process or a PV D process deposits metal fill layer on n-type work function layer and p-type work function layer, such that metal fill layer fills any remaining portion of gate trenches 875. Metal fill layer includes a suitable conductive material, such as Al, W, and/or Cu. Metal fill layer may additionally or collectively include other metals, metal oxides, metal nitrides, other suitable materials, or combinations thereof.

In the depicted embodiments where the gate electrodes 884A in n-type gate regions 840-1 and the gate electrodes 884B in p-type gate regions 840-2 are different in composition (such as with different work function metal layers), the gate electrodes 884A in n-type gate regions 840-1 and the gate electrodes 884B in p-type gate regions 840-2 are respectively formed by a suitable procedure that includes depositions, etchings, patterning processes or a combination thereof. A patterning process includes a lithography process and etching, such as wet etching, dry etching or a combination thereof.

In some embodiments, a planarization process may be performed to remove excess gate materials from the IC structure 800. For example, a CMP process is performed until a top surface of IL D layer 870 is reached (exposed), such that a top surface of gate structures 840 are substantially planar with a top surface of ILD layer 870 after the CMP process.

The present disclosure provides for many different embodiments. An exemplary method forming a gate dielectric layer in a gate trench in a gate structure. The gate dielectric layer is formed around first channel layers in a p-type gate region and around second channel layers in an n-type gate region. The method further includes forming a p-type work function layer in the gate trench over the gate dielectric layer in the p-type gate region and the n-type gate region. The method further includes forming an n-type work function layer in the gate trench over the gate dielectric layer in the n-type gate region. The n-type work function layer surrounds the gate dielectric layer and the second channel layers in the n-type gate region. The method further includes forming a metal fill layer in the gate trench over the p-type work function layer in the p-type gate region and the n-type work function layer in the n-type gate region. In some embodiments, the n-type work function layer is also formed in the gate trench over the p-type work function layer in the p-type gate region. In such embodiments, the n-type work function layer is disposed above gate spacers of the gate structure and the gate trench is free of the n-type work function layer along a gate length of the gate trench in the p-type gate region. In such embodiments, the n-type work function layer is removed from the gate trench in the p-type gate region before forming the metal fill layer.

Referring to FIG. 24, fabrication may proceed to continue fabrication of IC structure 800. For example, an interconnect structure 886 is formed to couple the n-type GAA transistors and the p-type GA A transistors other devices into an integrated circuit and facilitate operation thereof. The interconnect structure 886 is formed on the frontside of the semiconductor substrate 802 and therefore is referred to as a frontside interconnect structure. The frontside interconnect structure 886 includes contacts, vias and metal lines configured to provide vertical and horizontal routing. In some embodiments, the metal lines are distributed in multiple metal layers. For example, one or more ILD layers, similar to ILD layer 870, and/or CESL layers can be formed over substrate 802 (in particular, over ILD layer 870 and gate structures 840). Contacts can then be formed in ILD layer 870 and/or ILD layers disposed over ILD layer 870. For example, contacts are respectively electrically and/or physically coupled with gate structures 840 and contacts are respectively electrically and/or physically coupled to source/drain regions of the n-type GAA transistors and the p-type GAA transistors (particularly, epitaxial source/drain features 860A, 860B), such as contact 887. Contacts include a conductive material, such as metal. Metals include aluminum, aluminum alloy (such as aluminum/silicon/copper alloy), copper, copper alloy, titanium, titanium nitride, tantalum, tantalum nitride, tungsten, polysilicon, metal silicide, other suitable metals, or combinations thereof. The metal silicide may include nickel silicide, cobalt silicide, tungsten silicide, tantalum silicide, titanium silicide, platinum silicide, erbium silicide, palladium silicide, or combinations thereof. In some implementations, IL D layers disposed over ILD layer 870 and the contacts (for example, extending through ILD layer 870 and/or the other ILD layers) are a portion of the MLI feature described above.

Now turning to FIGS. 25-27, bond a carrier substrate 888 to the workpiece 800 on the frontside; thin down the semiconductor substrate 802 from the backside; and form an interconnect structure 892 on the backside of the semiconductor substrate 802. The detailed operations to form the backside interconnect structure 892 are further described below according to some embodiments.

Referring to FIG. 25, a carrier substrate 888 is bonded to the frontside of the workpiece 800 (the frontside of the semiconductor substrate 802 using any suitable bonding technology. The carrier substrate 888 provides a mechanical strength to the IC structure 800 while processing on the backside of the semiconductor substrate 802.

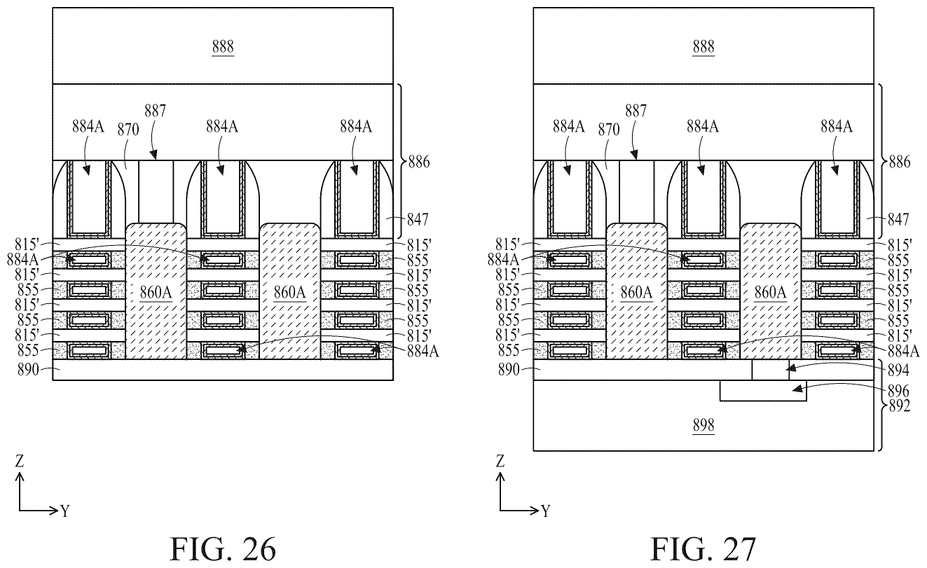

Referring to FIG. 26, the semiconductor substrate 802 is thinned down from the backside. In some embodiments, the thin-down process continues until the source/drain features are exposed from the backside. The thin-down process may include grinding, chemical mechanical polishing, etching, other suitable thinning process, or a combination thereof. In some embodiment, the thin-down process reduces the thickness of the substrate 802 such that the STI structure 830 is exposed from the backside. The carrier substrate 888 is a semiconductor substrate (such as a silicon substrate), a dielectric substrate or other suitable substrate according to various embodiments.

Still referring to FIG. 26, a dielectric layer 890 may be formed on the backside of the semiconductor substrate 802 by a suitable method. The dielectric layer 890 functions as a backside interlayer dielectric layer to provide isolation for various conductive features in the backside interconnect structure 892. The dielectric layer 890 includes silicon oxide, silicon nitride, silicon oxynitride, low-k dielectric material, other suitable dielectric material or a combination thereof. In some embodiments, the dielectric layer 890 includes an etch stop layer (such as silicon nitride) and a bulk dielectric material (such as silicon oxide) on the etch stop layer. The method to form the dielectric layer 890 includes deposition, such as CVD, flowable CVD (FCVD), spin-on coating, low pressure CVD (LPCVD), other suitable deposition or a combination thereof. The method may further include a CMP process to planarize the surface after the deposition.

Referring to FIG. 27, the backside interconnect structure 892 including backside contacts 894 are formed on the backside and configured to contact a subset of the source/drain features 860 (including 860A and 860B) and the gate structures 840. In the disclosed embodiments, the backside interconnect structure 892 includes contacts 894 and metal lines 896 formed in the dielectric layer 890 and other backside interlayer dielectric layers such as 898. In the depicted embodiment, the backside interlayer dielectric layer 898 is similar to the dielectric layer 890 in terms of composition and formation. The backside interconnect structure 892 is similar to the frontside interconnect structure 886 in terms of composition and formation. For example, the contacts 894 includes metal (such as aluminum, copper, nickel, tungsten), metal alloy such as copper aluminum, other suitable conductive material or a combination thereof. The contacts 894 may include a barrier layer (such as titanium and titanium nitride) and a bulk conductive layer (such as copper or tungsten) on the barrier layer. The contacts 894 is formed by a damascene process that includes patterning the dielectric layer 890 to form trenches; depositing one or more conductive material in the trenches; and performing a CMP process to remove excess deposited conductive material and planarize the surface. The metal lines 896 are formed in the backside interlayer dielectric layer 898 and may be formed by a damascene process. In some embodiments, the contacts 894 and 896 are collectively formed by a dual damascene process that includes patterning the dielectric layer 890 and the backside interlayer dielectric layer 898 to form trenches and contact holes; depositing one or more conductive material into the trenches and contact holes; and performing a CMP process to remove excess deposited conductive material and planarize the surface.

The present disclosure provides various embodiments of an integrated circuit structure having SRAM array with configuration and connection distributed on the frontside and the backside of the substrate. A subset of WBL, WBLB, RBL, Vss and Vdd are formed on the frontside and another subset of WBL, WBLB, RBL, Vss and Vdd are formed on the backside of the substrate. In some embodiments, the adjacent SRAM bit cells are configured asymmetrically to enhance circuit performance, such as induced parasitic capacitance, reduced resistance and reduced coupling among metal lines WBL, WBLB, RBL, Vss and Vdd.

The present disclosure provides ab IC structure and a method making the same. In one aspect, the present disclosure provides a semiconductor structure that includes a substrate having a frontside and a backside a static random-access memory (SRA M) circuit having SRAM bit cells formed on the frontside of the substrate, wherein each of the SRAM bit cells includes two inverters cross-coupled together, two write pass gates coupled to the two inverters, a read pull-down device coupled to the two inverters, and a read pass gate coupled to the read pull-down device, and wherein each of the SRAM bit cells is connected to a write bit line (WBL), a complimentary write bit line (WBLB), a read bit line (RBL), a first power line (Vdd) and a second power line (Vss); a first subset of WBL, WBLB, RBL, Vdd and Vss is connected to a first SRAM bit cell of the SRAM bit cells from the frontside of the substrate; and a second subset of WBL, WBLB, RBL, Vdd and Vss is connected to the first SRAM bit cell from the backside of the substrate.

In another aspect, the present disclosure provides a semiconductor structure that includes a substrate having a frontside and a backside; a static random-access memory (SRAM) circuit having SRAM bit cells formed on the frontside of the substrate, wherein each of the SRAM bit cells includes two inverters cross-coupled together, two write pass gates coupled to the two inverters, a read pull-down device coupled to the two inverters, and a read pass gate coupled to the read pull-down device, and wherein a first one of the SRAM bit cells is connected to a write bit line (WBL), a complimentary write bit line (WBLB), a write word line (WWL), a read word line (RWL), a read bit line (RBL), a first power line (Vdd) and a second power line (Vss); a first subset of WBL, WBLB, RBL, Vdd and Vss is connected to the first SRAM bit cell from the frontside of the substrate; WWL and RWL are connected to the first SRAM bit cell from the frontside of the substrate; and a second subset of WBL, WBLB, RBL, Vdd and Vss is connected to the first SRAM bit cell from the frontside of the substrate.

In yet another aspect, the present disclosure provides a semiconductor structure that includes a substrate having a frontside and a backside; a static random-access memory (SRAM) circuit having SRAM bit cells formed on the frontside of the substrate, wherein each of the SRAM bit cells includes two inverters cross-coupled together, two write pass gates coupled to the two inverters, a read pull-down device coupled to the two inverters, and a read pass gate coupled to the read pull-down device, and wherein a first one of the SRAM bit cells is connected to a write bit line (WBL), a complimentary write bit line (WBLB), a write word line (WWL), a read word line (RWL), a read bit line (RBL), a first power line (Vdd) and a second power line (Vss); a first subset of WBL, WBLB, RBL, Vdd and Vss is connected to a first SRAM bit cell from the frontside of the substrate; a second subset of WBL, WBLB, RBL, Vdd and Vss is connected to the first SRAM bit cell from the frontside of the substrate; a third subset of WBL, WBLB, RBL, Vdd and Vss is connected to a second SRAM bit cell from the frontside of the substrate; and a fourth subset of WBL, WBLB, RBL, Vdd and Vss is connected to the second SRAM bit cell from the frontside of the substrate, wherein the first subset is different from third subset.

The foregoing has outlined features of several embodiments. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. A semiconductor structure, comprising:
a substrate having a frontside and a backside;
a static random-access memory (SRAM) circuit having SRAM bit cells formed on the frontside of the substrate, wherein each of the SRAM bit cells includes two inverters cross-coupled together, two write pass gates coupled to the two inverters, a read pull-down device coupled to the two inverters, and a read pass gate coupled to the read pull-down device, and wherein each of the SRAM bit cells is connected to a write bit line (WBL), a complimentary write bit line (WBLB), a read bit line (RBL), a first power line (Vdd) and a second power line (Vss);
a first subset of WBL, WBLB, RBL, Vdd and Vss is connected to a first SRAM bit cell of the SRAM bit cells from the frontside of the substrate; and
a second subset of WBL, WBLB, RBL, Vdd and Vss is connected to the first SRAM bit cell from the backside of the substrate.

2. The semiconductor structure of claim 1, further comprising:
a frontside interconnect structure formed on the frontside of the substrate; and
a backside interconnect structure formed on the backside of the substrate, wherein
the first subset of WBL, WBLB, RBL, Vdd and Vss is connected to the first SRAM bit cell through first conductive features of the frontside interconnect structure, and
the second subset of WBL, WBLB, RBL, Vdd and Vss is connected to the first SRAM bit cell through second conductive features of the backside interconnect structure.

3. The semiconductor structure of claim 2, wherein
the first subset includes RBL, Vdd and Vss; and
the second subset includes WBL, WBLB and Vss.

4. The semiconductor structure of claim 3, wherein
the first conductive features include a first metal line connected to Vdd having a first width;
the first conductive features include a second metal line connected to RBL having a second width greater than the first width;
the second conductive features include a third metal line connected to Vss having a third width; and
the second conductive features include a fourth metal line connected to WBL having a fourth width greater than the third width.

5. The semiconductor structure of claim 2, wherein
the first subset includes WBL, WBLB, Vdd and Vss; and
the second subset includes RBL and Vss.

6. The semiconductor structure of claim 2, wherein
the first subset includes WBL, WBLB, Vdd and Vss; and
the second subset includes RBL, Vdd and Vss.

7. The semiconductor structure of claim 1, wherein WWL and RWL are connected to the first SRAM bit cell from the frontside of the substrate.

8. The semiconductor structure of claim 1, wherein
a third subset of WBL, WBLB, RBL, Vdd and Vss is connected to a second SRAM bit cell from the frontside of the substrate;
a fourth subset of WBL, WBLB, RBL, Vdd and Vss is connected to the second SRAM bit cell from the backside of the substrate; and
the third subset is different from the first subset.

9. The semiconductor structure of claim 8, wherein
the first subset includes RBL, Vdd and Vss; and
the third subset includes WBL, WBLB and Vss.

10. The semiconductor structure of claim 8, wherein
the first subset includes WBL, WBLB, Vdd and Vss; and
the third subset includes RBL and Vss.

11. The semiconductor structure of claim 1, wherein the SRAM bit cells include field effect transistors each including plurality of channels stacked vertically, a gate structure wrapping around each of the plurality of channels, and a source and a drain interposed on opposite sides of the gate structure and connecting to each of the plurality of channels.

12. A semiconductor structure, comprising:
a substrate having a frontside and a backside;
a static random-access memory (SRAM) circuit having SRAM bit cells formed on the frontside of the substrate, wherein each of the SRAM bit cells includes two inverters cross-coupled together, two write pass gates coupled to the two inverters, a read pull-down device coupled to the two inverters, and a read pass gate coupled to the read pull-down device, and wherein a first one of the SRAM bit cells is connected to a write bit line (WBL), a complimentary write bit line (WBLB), a write word line (WWL), a read word line (RWL), a read bit line (RBL), a first power line (Vdd) and a second power line (Vss);
a first subset of WBL, WBLB, RBL, Vdd and Vss is connected to the first SRAM bit cell from the frontside of the substrate;
WWL and RWL are connected to the first SRAM bit cell from the frontside of the substrate; and
a second subset of WBL, WBLB, RBL, Vdd and Vss is connected to the first SRAM bit cell from the frontside of the substrate.

13. The semiconductor structure of claim 12, further comprising:
a frontside interconnect structure formed on the frontside of the substrate; and
a backside interconnect structure formed on the backside of the substrate, wherein
the first subset of WBL, WBLB, RBL, Vdd and Vss is connected to the first SRAM bit cell through first conductive features of the frontside interconnect structure, and
the second subset of WBL, WBLB, RBL, Vdd and Vss is connected to the first SRAM bit cell through second conductive features of the backside interconnect structure.

14. The semiconductor structure of claim 12, wherein
the first subset includes RBL, Vdd and Vss;
the second subset includes WBL, WBLB and Vss; and
WWL and RWL are connected to the first SRA M bit cell from the frontside of the substrate.

15. A semiconductor structure, comprising:
a substrate having a frontside and a backside;
a static random-access memory (SRAM) circuit having SRAM bit cells formed on the frontside of the substrate, wherein each of the SRAM bit cells includes two inverters cross-coupled together, two write pass gates coupled to the two inverters, a read pull-down device coupled to the two inverters, and a read pass gate coupled to the read pull-down device, and wherein a first one of the SRAM bit cells is connected to a write bit line (WBL), a complimentary write bit line (WBLB), a write word line (WWL), a read word line (RWL), a read bit line (RBL), a first power line (Vdd) and a second power line (Vss);
a first subset of WBL, WBLB, RBL, Vdd and Vss is connected to a first SRAM bit cell from the frontside of the substrate;
a second subset of WBL, WBLB, RBL, Vdd and Vss is connected to the first SRAM bit cell from the frontside of the substrate;
a third subset of WBL, WBLB, RBL, Vdd and Vss is connected to a second SRAM bit cell from the frontside of the substrate; and
a fourth subset of WBL, WBLB, RBL, Vdd and Vss is connected to the second SRAM bit cell from the frontside of the substrate, wherein the first subset is different from third subset.

16. The semiconductor structure of claim 15, wherein WWL and RWL are connected to the first and second SRAM bit cells from the frontside of the substrate.

17. The semiconductor structure of claim 16, wherein WWL and RWL are connected to the first SRAM bit cell from the frontside of the substrate.

18. The semiconductor structure of claim 15, wherein
the first subset includes RBL, Vdd and Vss; and
the third subset includes WBL, WBLB and Vss.

19. The semiconductor structure of claim 15, wherein
the first subset includes WBL, WBLB, Vdd and Vss; and
the third subset includes RBL and Vss.

20. The semiconductor structure of claim 15, wherein
the first subset includes WBL, WBLB, Vdd and Vss; and
the third subset includes RBL, Vdd and Vss.
